(19) United States
(12) Patent Application Publication
(10) Pub. No.: US 2026/0349144 A1
(43) Pub. Date: Nov. 5, 2026

(54) PROBABILISTIC SOILING-INFORMED PHOTOVOLTAIC WASH OPTIMIZATION

(71) Applicant: BrightNight Power LLC, West Palm Beach, FL (US)

(72) Inventor: Cédric Leroy, Orinda, CA (US)

(73) Assignee: BrightNight Power LLC, West Palm Beach, FL (US)

(21) Appl. No.: 19/706,646

(22) Filed: Jun. 12, 2026

Related U.S. Application Data
(63) Continuation-in-part of application No. PCT/US2026/013384, filed on Feb. 4, 2025.

(51) Int. Cl. G01W 1/10; B08B 3/04; B08B 13/00; H02S 40/10

(52) U.S. Cl. CPC G01W 1/10; B08B 3/04; B08B 13/00; H02S 40/10

(57) ABSTRACT

A computing system can generate a plurality of cleaning event scenarios for a photovoltaic array. Generating each cleaning event scenario can include generating predicted weather events to estimate a probability and effectiveness of natural cleaning events. The system can generate predicted soiling losses using the probability and effectiveness of natural cleaning events. The system can generate predicted power output using the predicted weather events and the predicted soiling losses. The system can determine a predicted energy gain from a candidate manual cleaning event using the predicted power output. The system can determine a predicted revenue gain from the candidate manual cleaning event using the predicted energy gain. The system can generate a recommendation for a manual cleaning event based on the predicted revenue gain of the candidate manual cleaning event of each of the plurality of cleaning event scenarios and cause implementation of the recommendation.

### CROSS-REFERENCE TO RELATED APPLICATIONS

This application is a Continuation-In-Part of PCT Application No. PCT/US2026/013384, filed Jan. 30, 2026, which claims priority to U.S. application Ser. No. 19/045,371, filed Feb. 4, 2025, now U.S. Pat. No. 12,488,162, which are each incorporated herein by reference in their entirety.

### BACKGROUND

Photovoltaic (PV) arrays generate electricity from solar radiation. Soiling of PV arrays, such as buildup of dust on PV arrays, reduces the power output of PV arrays. Forecasts of PV array output for controlling assets of a power plant can be inaccurate due to soiling of PV arrays and the corresponding reduction in output.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing.

FIG. 1 is a block diagram of an example computing system for optimizing a photovoltaic (PV) soiling model.

FIG. 2 is an example graph illustrating rainfall data and cleaning threshold parameters for a PV soiling model.

FIG. 3 is an example graph illustrating soiling rate parameter values for a PV soiling model.

FIG. 4 is an example graph illustrating predicted soiling losses and actual soiling losses.

FIG. 5 is an example graph illustrating soiling loss errors.

FIG. 6 is a flowchart illustrating operations of an example method for generating optimized parameters for a PV soiling model.

FIG. 7 is an example graph illustrating irradiance and irradiance modified by soiling losses.

FIG. 8 is an example graph illustrating soiling losses.

FIG. 9 is a flowchart illustrating operations of an example method for optimizing manual cleaning events.

FIG. 10 is a block diagram of an example system for probabilistic soiling-informed photovoltaic wash optimization.

FIG. 11 is a block diagram of the Monte Carlo engine of FIG. 10.

FIG. 12 is a block diagram of the scenario builder of FIG. 11.

FIG. 13 is a flowchart illustrating operations of an example method for optimizing manual cleaning events based on probabilistic weather predictions.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

Photovoltaic power plants convert solar radiation into electrical energy through arrays of PV modules. The performance of PV modules can degrade over time due to the accumulation of particulate matter, such as dust, pollen, bird droppings, or other debris, on module surfaces. The accumulation of particulate matter on PV modules, referred to as soiling, reduces the amount of solar irradiance reaching the photovoltaic cells and correspondingly reduces energy production. Cleaning events, whether performed manually by personnel or automatically by robotic systems, can restore PV module performance by removing accumulated soiling. However, cleaning events incur direct costs, including labor, equipment, water, and operational constraints. Natural cleaning events, such as rainfall of sufficient intensity and duration, can reduce or eliminate soiling without incurring direct cleaning costs. The decision of whether and when to perform a cleaning event involves balancing the expected energy recovery against cleaning expenses and the likelihood of natural cleaning by rainfall.

Existing approaches to PV cleaning decisions typically rely on fixed-interval cleaning schedules or simple threshold-based heuristics, such as performing a cleaning event when soiling exceeds a predetermined percentage. Fixed-interval schedules do not account for variations in soiling accumulation rates, weather patterns, or seasonal energy production. Threshold-based heuristics do not account for the probability of imminent rainfall that could provide natural cleaning, potentially resulting in unnecessary cleaning events performed shortly before rainfall. Existing approaches do not incorporate site-specific calibrated soiling accumulation and removal behavior, probabilistic rainfall occurrence and intensity, site production seasonality, long-term historical climate variability, or comprehensive economic evaluation that incorporates uncertainty and risk. As a result, existing approaches can lead to suboptimal decisions, including unnecessary cleaning before imminent rainfall or delayed cleaning during prolonged dry periods.

Aspects of the present disclosure provide a system and method for determining whether and when a PV site should be cleaned by integrating calibrated soiling models, probabilistic meteorological information, optimization algorithms, and financial evaluation under uncertainty. In some implementations, a soiling accumulation model can be applied to represent temporal degradation of PV performance due to particulate deposition and natural cleaning events. The soiling model can be calibrated using historical and real-time site data via an optimization algorithm to estimate site-specific parameters including deposition rates, rain-induced cleaning thresholds, and cleaning efficiency coefficients. An energy production model can forecast expected PV generation over a forward-looking horizon while accounting for seasonal irradiance patterns, sun angle, temperature effects, and site-specific performance characteristics. Long-term historical meteorological data can be combined with short-term deterministic and ensemble weather forecasts to estimate the probability and effectiveness of natural cleaning events.

In some implementations, a system can generate a plurality of future weather-soiling-production scenarios using historical weather data and short-term weather forecasts. For each scenario, the system can compute economic outcomes for both a clean-now case and a do-not-clean case. The system can compute one or more quantitative decision metrics, such as an expected incremental net benefit, a probability of positive benefit, or a wash viability index (WVI). The WVI can be defined as a ratio of expected gross revenue benefit to cleaning cost. The system can compare the decision metrics to configurable thresholds and output a recommendation to perform or defer cleaning, optionally with confidence intervals or risk indicators. In some implementations, the system can generate a recommended cleaning window specifying a timeframe for action. In some implementations, the system can generate a confidence or risk summary providing probabilistic context for the recommendation.

Aspects of the present disclosure can quantify cleaning decisions using explicit economic and risk-based metrics rather than deterministic heuristics. Short-term forecasts can be combined with long-term climatological variability to produce probabilistic future weather trajectories. Seasonal energy production can be accounted for, providing that cleaning actions are timed relative to high-production and low-production periods to maximize economic benefit. The disclosed systems and methods can adapt to diverse climates, PV technologies, and cost structures by calibrating site-specific soiling model parameters. By integrating calibrated soiling models with probabilistic rainfall forecasting and economic evaluation under uncertainty, aspects of the present disclosure provide a technical improvement over existing fixed-interval and threshold-based approaches to PV cleaning decisions.

Implementations of the present disclosure can increase power output of PV arrays by optimizing the timing of cleaning events to maximize energy recovery while minimizing unnecessary cleaning costs. By accurately predicting soiling accumulation and the probability of natural cleaning events, the system can identify optimal windows for manual or robotic cleaning that avoid cleaning shortly before rainfall that would naturally restore module performance. The system can also identify periods of prolonged dry weather during high-production seasons where delayed cleaning would result in significant cumulative energy losses. By quantifying the expected economic benefit of cleaning under uncertainty, the system enables operators to make informed decisions that balance cleaning costs against energy recovery, resulting in increased net energy production over time compared to fixed-interval or threshold-based approaches.

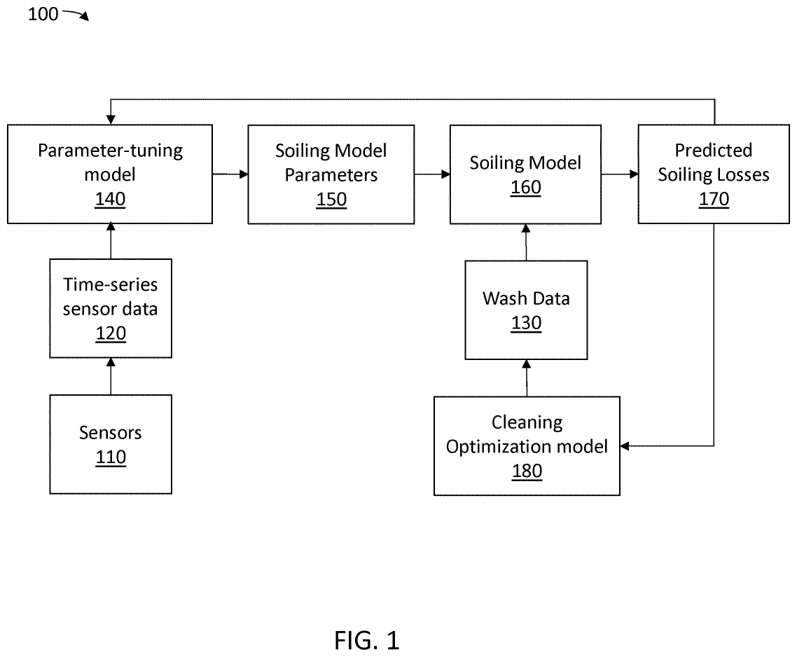

FIG. 1 is a block diagram of an example system 100 for optimizing a photovoltaic (PV) soiling model 160. The system 100 optimizes parameters of the soiling model 160 to provide accurate predictions of soiling losses. The system 100 optimizes wash schedules to optimize power generation by PV arrays. In this way, the system 100 can improve the design, implementation, control, and maintenance of PV systems to increase efficiency of power generation.

The system 100 includes sensors 110. The sensors 110 can include sensors of meteorological stations (met stations) adjacent PV arrays to capture data corresponding to the PV arrays. The sensors 110 can include soiling sensors, irradiance sensors, rainfall sensors, humidity sensors, and other sensors. The sensors 110 can provide time-series sensor data 120 associated with a location of the sensors 110. The sensors 110 can be in a location of a PV plant, or a location of a potential PV plant such that the time-series sensor data 120 can be used to optimize the soiling model 160 for the location.

The time-series sensor data 120 can be used to calculate soiling loss data. The soiling loss data represents a loss in power that could be generated by a PV array due to soiling of the PV array. In an example, the soiling loss data includes soiling losses due to buildup of dust on a PV array, indicating a percentage of theoretical output of the PV array that is lost due to the reduction in irradiance on the PV array due to the dust. In an example, the soiling loss data includes soiling losses due to dust on the PV array. The soiling loss data can be calculated based on data in the time-series sensor data 120. In an example, the soiling loss data is calculated based on a difference between an irradiance measured by an irradiance sensor that experiences no soiling (e.g., due to cleaning, geometry and/or other factors) and an irradiance measured by an irradiance sensor that experiences soiling. In an example, the soiling loss data is calculated based on a difference between a theoretical output of a PV array calculated using an irradiance measured by an irradiance sensor and an actual output of the PV array. In some implementations, the soiling loss data is calculated by an intermediate computing device that receives the time-series sensor data 120 and calculates the soiling loss data.

The soiling model 160 can be used to predict soiling losses for the location. The soiling model 160 can generate predicted soiling losses 170. The predicted soiling losses 170 can include predictions of soiling losses for past, current, and/or future time periods. The predicted soiling losses 170 can be used to modify and/or generate predicted PV outputs. In an example, the predicted soiling losses 170 include percentages of irradiance lost and/or power output lost due to soiling, which percentages are used to modify a prediction of PV output. The soiling model 160 can use a parameter set to configure the soiling model and be executed using as input rainfall data to output the predicted soiling losses 170. In an example, the soiling model is the Kimber soiling model.

The soiling model 160 is executed using as input soiling model parameters 150 and wash data 130. In some implementations, the soiling model 160 is executed using as input the soiling model parameters 150, the wash data 130, and tilt data (i.e., tilt of PV arrays). The soiling model parameters 150 determine a configuration of the soiling model 160. The soiling model parameters 150 can include a soiling buildup rate (e.g., for each month), a cleaning threshold defining an amount of rain required for a cleaning event, a rain accumulation period defining a time interval for accumulating rainfall to compare against the cleaning threshold, a grace period defining a number of days after a rainfall event during which no soiling occurs due to residual moisture (e.g., ground is damp and no dust is picked up by wind), and/or initial soiling defining an initial soiling level on PV arrays. The soiling model parameters 150 can be specific to a location, or can include different sets of parameters for different locations.

The wash data 130 can include rainfall data and manual cleaning data. The rainfall data can include historical and/or forecasted rainfall data. The rainfall data can be provided by the sensors 110 or from a rainfall database. The rainfall data, the soiling model parameters 150, and the time-series sensor data 120 correspond to a same location to accurately model soiling losses on PV arrays at the location using the soiling model 160. Different sets of rainfall data, soiling model parameters, and time-series sensor data can be used to optimize the soiling model 160 for different locations. The manual cleaning data defines manual cleaning events when soiling is removed from PV arrays without rainfall, such as by washing the PV arrays. The manual cleaning events can include manual cleaning processes as well as automated cleaning processes, such as cleaning by automatic sprinkler systems or automatic pneumatic cleaning systems. The manual cleaning data can include any intervention to clean PV arrays, separate from natural cleaning of the PV arrays caused by rainfall.

A parameter-tuning model 140 can generate and/or optimize the soiling model parameters 150. The parameter-tuning model 140 can generate the soiling model parameters 150 using as input the time-series sensor data 120 and the predicted soiling losses 170. In some implementations, the parameter-tuning model 140 initializes the soiling model parameters 150 with random (pseudo-random) parameters or user-provided parameters and compares the predicted soiling losses 170 to the time-series sensor data 120 (including actual soiling losses) to determine a loss between the predicted soiling losses 170 and the actual soiling losses, or an accuracy of the soiling model 160 using the current soiling model parameters 150. The parameter-tuning model 140 compares the loss to a predetermined loss threshold, or compares the accuracy to a predetermined accuracy threshold to determine whether to further optimize the soiling model parameters 150. If the loss is above the predetermined loss threshold, or the accuracy is below the predetermined accuracy threshold, the parameter-tuning model 140 uses the loss or accuracy to modify the current soiling model parameters 150 or generate new soiling model parameters 150. In this way, the parameter-tuning model 140 can iteratively improve the soiling model parameters 150 to improve the accuracy of the soiling model 160 and reduce a loss between the predicted soiling losses 170 and the actual soiling losses. In some implementations, the parameter-tuning model 140 improves the soiling model parameters over a predetermined number of iterations.

In some implementations, the parameter-tuning model 140 initializes the soiling model parameters 150 with a plurality of parameter sets, where each parameter set includes the parameters for configuring the soiling model 160. The soiling model 160 is executed using as input each parameter set to generate corresponding predicted soiling losses 170, and a corresponding loss is calculated based on a difference between the corresponding predicted soiling losses 170 and the actual soiling losses. The parameter-tuning model 140 ranks the plurality of parameter sets based on the calculated losses to select a subset of the plurality of parameter sets having lowest corresponding losses. The parameter-tuning model 140 is executed using as input the selected subset to generate a new plurality of parameter sets of soiling model parameters 150 which are used in executing the soiling model 160 to generate new corresponding predicted soiling losses 170. The parameter-tuning model 140 can introduce randomness into the generation of the new plurality of parameter sets to avoid local minima. The new corresponding predicted soiling losses 170 are used to calculate losses based on a difference from the actual soiling losses to evaluate the new plurality of parameter sets. The parameter-tuning model 140 iteratively generates subsequent parameter sets based on prior parameter sets ranked according to their losses (difference from the actual soiling losses). Once a loss for a parameter set is below a predetermined threshold, the parameter-tuning model 140 generates a data structure including the parameter set. The data structure can be a configuration file for the soiling model 160 for execution of the soiling model 160 in predicting PV soiling losses in the location corresponding to the sensors 110. In this way, the parameter-tuning model 140 can optimize the soiling model parameters 150 for the location. The data structure can be a CSV file, a JSON file, a text file, or any data structure for storing the selected parameter set.

In some implementations, the parameter-tuning model 140 includes a derivative-free optimization algorithm. In an example, the parameter-tuning model 140 includes a particle swarm optimization (PSO) algorithm. In some implementations, the parameter-tuning model 140 includes a machine-learning model trained to adjust the soiling model parameters 150 to minimize a loss between the predicted soiling losses 170 and the actual soiling losses.

In some implementations, the loss calculated based on the difference between the predicted soiling losses 170 and the actual soiling losses is an absolute average difference between a predicted percentage energy loss and a measured percent energy loss. In an example, the predicted soiling losses 170 include soiling losses over the course of a year, and the loss is calculated by averaging an absolute difference between the predicted soiling losses 170 and the actual soiling losses for each day. In some implementations, the loss is calculated using weighted values. In an example, losses in summer months are weighted higher than losses in winter months, as losses in summer months represent greater absolute differences in power output due to higher irradiance in summer months. In an example, losses in winter months are weighted higher than losses in summer months, as losses in winter months represent greater proportions of power output due to lower irradiance in winter months.

In some implementations, the soiling model parameters 150 include at least one of a soiling buildup rate, a rain cleaning threshold, a rain accumulation period, and a grace period, as discussed herein. The parameter-tuning model 140 can adjust one or more or more of the parameters using various rules. In an example, the parameter-tuning model 140 adjusts values of the soiling buildup rate based on adjacent values or an average value. In an example, the soiling buildup rate includes twelve values for monthly soiling buildup rates for each month in a year, and the parameter-tuning model 140 adjusts the value for each month based on the values of the neighboring months, or the average yearly soiling buildup. In this way, the parameter-tuning model 140 prevents sudden changes in the values of the soiling buildup rate across different months.

The soiling model 160 can be executed using the optimized soiling model parameters 150 (e.g., the selected parameter set) to generate the predicted soiling losses 170 for applying to predicted PV output. The predicted soiling losses 170 can be used to adjust (i.e., reduce) the predicted PV output to take into account losses due to soiling. In an example, the predicted soiling losses 170 include a percentage loss of irradiance on PV arrays which is used to calculate a predicted output of the PV arrays using irradiance data. In an example, the predicted soiling losses 170 include a percentage loss of PV output which is used to calculate a predicted output of the PV arrays using a preliminary predicted PV output.

The soiling model 160 can be executed using the optimized soiling model parameters 150 (e.g., the selected parameter set) to optimize manual cleaning events. In some implementations, the soiling model 160 is executed multiple times using modified wash data 130 each time to determine which wash data 130 (i.e., which cleaning events) results in the lowest predicted soiling losses 170. In an example, the soiling model 160 is executed ten times using the optimized soiling model parameters 150 and ten different combinations of cleaning dates to determine which combination of cleaning dates results in the lowest predicted soiling losses 170. In this way, the system 100 can generate a recommendation for one or more manual cleaning events (e.g., cleaning dates) by executing the soiling model 160 using as input the modified cleaning data.

In some implementations, a cleaning optimization model 180 is used to optimize the manual cleaning events of the wash data 130. The cleaning optimization model 180 iteratively modifies the manual cleaning events based on the predicted soiling losses 170 to determine manual cleaning events that result in lowest predicted soiling losses 170. In some implementations, the cleaning optimization model 180 initializes the wash data 130 with random (pseudo-random) combinations of manual cleaning events (e.g., wash dates), the soiling model 160 is executed using as input the wash data 130 including rainfall data and the combinations of manual cleaning events to generate the predicted soiling losses 170, the cleaning optimization model 180 ranks the combinations of manual cleaning events according to the corresponding predicted soiling losses 170, and the cleaning optimization model 180 selects and/or generates new manual cleaning events based on the ranking of the combinations of manual cleaning events. In this way, the cleaning optimization model 180 can optimize the manual cleaning events to minimize the predicted soiling losses 170. In some implementations, the cleaning optimization model 180 generates a data structure including the optimized manual cleaning events. In some implementations, the data structure including the optimized manual cleaning events is provided as input to an automatic cleaning system to optimize an efficiency of the automatic cleaning system.

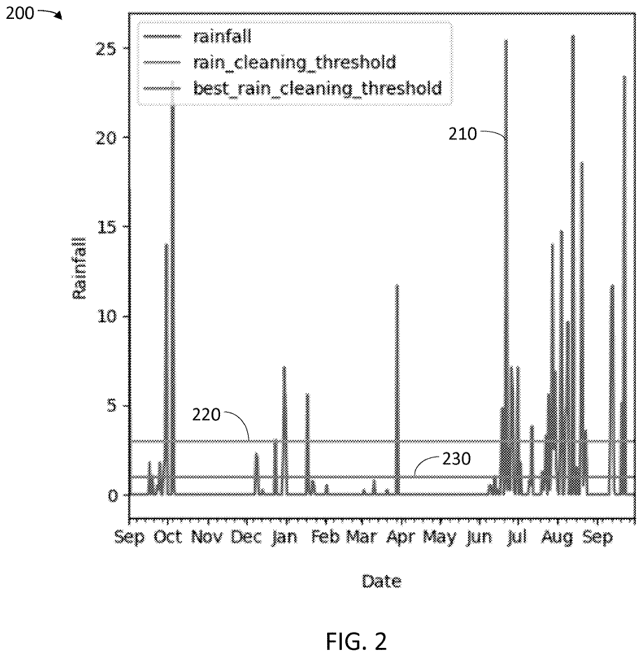

FIG. 2 is an example graph 200 illustrating rainfall data 210 and cleaning threshold parameters for a PV soiling model. The cleaning threshold parameters include a first rain cleaning threshold 220 and a second rain cleaning threshold 230. The first rain cleaning threshold 220 and the second rain cleaning threshold 230 can each be parameters in the soiling model parameters 150 for configuring the soiling model 160 of FIG. 1. The first rain cleaning threshold 220 and the second rain cleaning threshold 230 represent amounts of rainfall (e.g., mm) for a cleaning event, where the cleaning event removes all or a portion of soiling buildup on PV arrays. The first rain cleaning threshold 220 and the second rain cleaning threshold 230 have different values, with the first rain cleaning threshold 220 being higher than the second rain cleaning threshold 230. Thus, the first rain cleaning threshold 220 and the second rain cleaning threshold 230, when applied to the rainfall data 210, result in different cleaning events, with the first rain cleaning threshold 220 resulting in fewer cleaning events than the second rain cleaning threshold 230.

In some implementations, the first rain cleaning threshold 220 may be an initial rain cleaning threshold parameter, such as a pseudo-random parameter to initialize the soiling model parameters 150 of FIG. 1. In some implementations, the first rain cleaning threshold 220 may be generated by a deterministic algorithm that generates the first rain cleaning threshold 220 based on factors such as humidity, average wind speed, and PV array tilt. The second rain cleaning threshold 230 may be a subsequent, optimized, and/or selected rain cleaning threshold parameter generated by the parameter-tuning model 140 of FIG. 1. The second rain cleaning threshold 230 may more accurately represent how much rain is needed to clean soiling from PV arrays in the location of the PV arrays, resulting in more accurate soiling losses when applied to a soiling model than the first rain cleaning threshold 220.

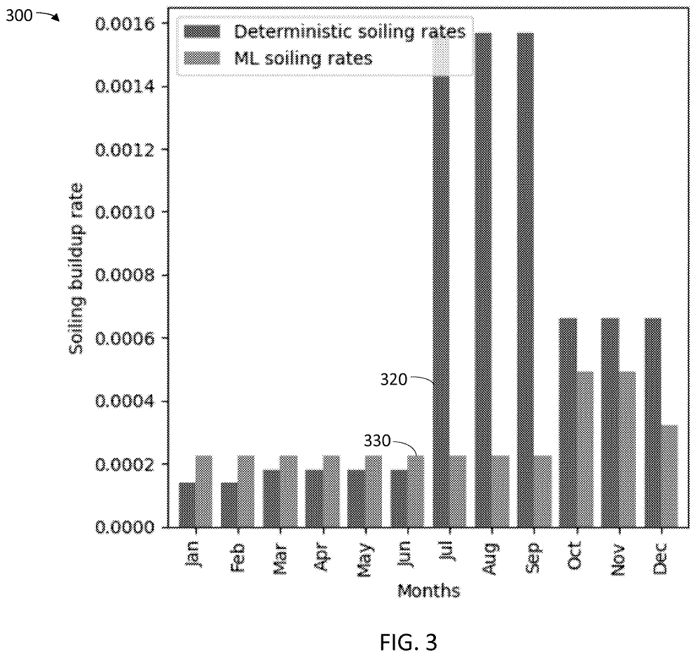

FIG. 3 is an example graph 300 illustrating soiling rate parameter values for a PV soiling model, such as the soiling model 160 of FIG. 1. The soiling rate parameter values of the graph 300 include first soiling rate parameter values 320 and second soiling rate parameter values 330 for each month in a year. The first soiling rate parameter values 320 and the second soiling rate parameter values 330 are parameters for the PV soiling model that represent a monthly soiling buildup for PV arrays in a location. The first soiling rate parameter values 320 and the second soiling rate parameter values 330 represent how much soiling loss is added to a cumulative soiling loss each month. As discussed herein, cleaning events such as rainfall cleaning events and manual cleaning events reset the soiling buildup to zero, such that the cumulative soiling loss is reduced (i.e., reset) based on cleaning events and increased based on the first soiling rate parameter values 320 or the second soiling rate parameter values 330. The monthly soiling buildup may be prorated for each day or hour of the month. While the graph illustrates monthly soiling buildup rates, other time periods can be used, such as quarters, weeks, days, or hours.

In some implementations, the first soiling rate parameter values 320 may be initial soiling rate parameter values, such as pseudo-random parameter values to initialize the soiling model parameters 150 of FIG. 1 or user-provided soiling rate parameter values. In some implementations, the first soiling rate parameter values 320 may be generated by a deterministic algorithm that generates the first soiling rate parameter values 320 based on factors such as humidity, average wind speed, and PV array tilt. The second soiling rate parameter values 330 may be subsequent, optimized, and/or selected soiling rate parameter values generated by the parameter-tuning model 140 of FIG. 1. The second soiling rate parameter values 330 may be adjusted based on an average soiling rate of the second soiling rate parameter values 330 limiting differences in soiling rate parameter values between adjacent months (i.e., spread limit). The second soiling rate parameter values 330 more accurately represent soiling buildup on PV arrays in the location of the PV arrays, resulting in more accurate soiling losses when applied to a soiling model than the first soiling rate parameter values 320. The second soiling rate parameter values 330 more accurately represent the soiling buildup on the PV arrays, as the second soiling rate parameter values 330 were iteratively trained based on comparison to actual soiling data. The second soiling rate parameter values 330 more accurately represent the soiling buildup on the PV arrays due to the implementation of the spread limit, attenuating the effect of noise on the second soiling rate parameter values 330 and representing a more realistic scenario by avoiding overfitting of the second soiling rate parameter values 330 to the training data.

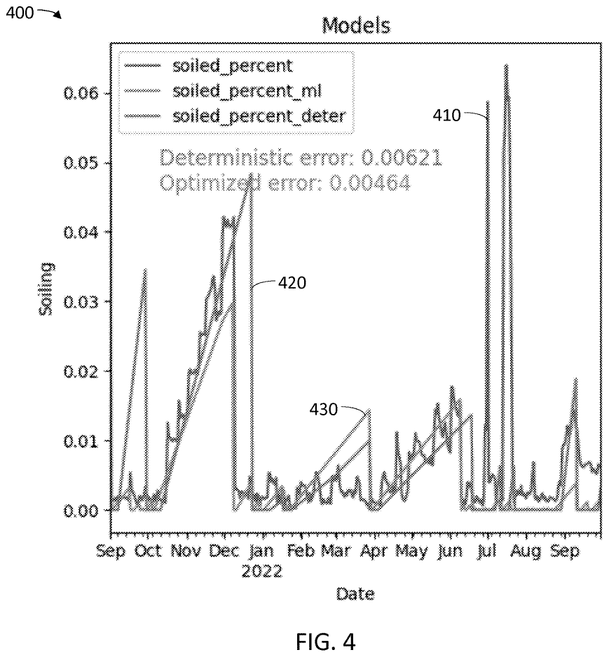

FIG. 4 is an example graph 400 illustrating predicted soiling losses and actual soiling losses 410. The predicted soiling losses include first soiling losses 420 and second soiling losses 430. The actual soiling losses 410, the first soiling losses 420, and the second soiling losses 430 represent percentage soiling losses to irradiance or PV output. The first soiling losses 420 may be generated by a soiling model (e.g., soiling model 160 of FIG. 1) using parameters generated by a deterministic algorithm that generates the parameters based on factors such as humidity, average wind speed, and PV array tilt. The first soiling losses 420 may be generated by a soiling model (e.g., soiling model 160 of FIG. 1) using user-provided parameters. The second soiling losses 430 may be generated by a soiling model (e.g., soiling model 160 of FIG. 1) using parameters generated by a parameter-tuning model (e.g., parameter-tuning model 140 of FIG. 1) that generates the parameters by iteratively optimizing to reduce a loss between predicted soiling losses and actual soiling losses such as the actual soiling losses 410. The parameters used by the soiling model to generate the second soiling losses 430 may more accurately reflect conditions in the location of the PV arrays than the parameters used by the soiling model to generate the first soiling losses 420, such that the second soiling losses 430 are more accurate than the first soiling losses 420. In the example graph 400, an average absolute error between the first soiling losses 420 and the actual soiling losses 410 is 0.00621, while an average absolute error between the second soiling losses 430 and the actual soiling losses 410 is 0.00464.

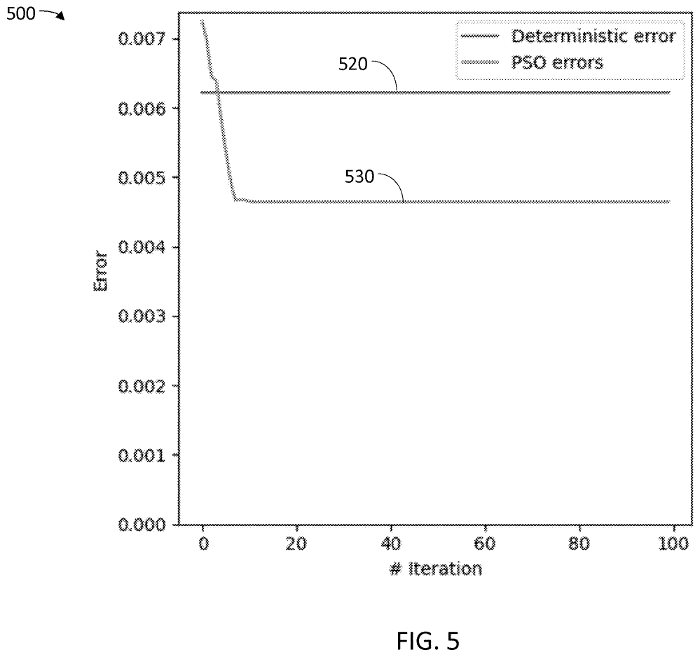

FIG. 5 is an example graph 500 illustrating soiling loss errors. The soiling loss errors include first soiling loss errors 520 and second soiling loss errors 530. The first soiling loss errors 520 and second soiling loss errors 530 correspond to errors of the first soiling losses 420 and the second soiling losses 430, respectively, of FIG. 4. The first soiling loss errors 520 and the second soiling loss errors 530 show error over iterations, where the first soiling loss errors 520 are constant at 0.00621 as the deterministic algorithm is unchanged, while the second soiling loss errors 530 decrease over iterations as the corresponding soiling model parameters are optimized. After about ten iterations, the second soiling loss errors 530 stabilize at 0.00464, as shown in FIG. 4. The second soiling loss errors 530 may be stable at a global minimum, or at a local minimum. In an example, the parameter-tuning model that generated the parameters resulting in the second soiling loss errors 530 may be a particle swarm optimization (PSO) model.

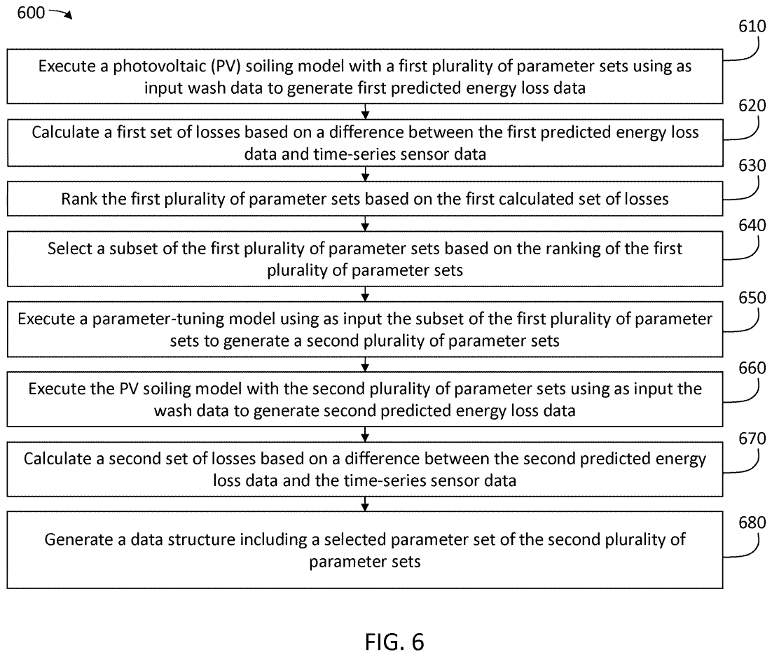

FIG. 6 is a flowchart illustrating operations of an example method 600 for generating optimized parameters for a PV soiling model. The method 600 may include more, fewer, or different operations than shown. The operations may be performed in the order shown, in a different order, or concurrently. The method 600 may be performed by one or more components of the system 100 of FIG. 1.

At operation 610, a PV soiling model (e.g., the soiling model 160 of FIG. 1) is executed with a first plurality of parameter sets using as input wash data to generate first predicted energy loss data. As discussed herein, the wash data includes rainfall data and/or manual cleaning data. The plurality of parameter sets each define how cleaning events are determined based on the rainfall data. In an example, each of the parameter sets includes a rain accumulation period and a rain cleaning threshold, where a cleaning event occurs when an amount of rain defined by the rain cleaning threshold is received within an amount of time defined by the rain accumulation period. Thus, different parameter sets applied to the rainfall data result in different cleaning events, resulting in different predicted energy loss data (e.g., soiling losses).

In some implementations, the method 600 includes initializing the first plurality of parameter sets using pseudo-random numbers. In some implementations, the first plurality of parameter sets are the result of prior iterations of optimizing parameter sets. As discussed herein, any number of iterations can be used to generate optimized parameter sets. In an example, FIG. 5 shows how approximately ten iterations of parameter set optimization resulted in parameter sets with a stable amount of error.

At operation 620, a first set of losses are calculated based on a difference between the first predicted energy loss data and time-series sensor data. The first set of losses may be an average absolute difference between actual soiling losses included in the time-series sensor data and the first predicted energy loss data. As discussed herein, the actual soiling losses can be calculated based on raw sensor data in the time-series sensor data, such as irradiance from a clean sensor and a soiled sensors, or irradiance from a clean sensor and output from a soiled PV array.

At operation 630, the first plurality of parameter sets are ranked based on the first calculated set of losses. The ranking may reflect an accuracy of the PV soiling model when using each of the first plurality of parameter sets.

At operation 640, a subset of the first plurality of parameter sets is selected based on the ranking of the first plurality of parameter sets. In an example, the subset includes the best 10% of the first plurality of parameter sets having the lowest corresponding losses, meaning that the subset caused the PV soiling model to more accurate than the remaining parameter sets in the plurality of parameter sets. In an example, the first plurality of parameter sets includes one hundred parameter sets and the subset includes the ten parameter sets that had the lowest corresponding losses.

At operation 650, a parameter-tuning model is executed using as input the subset of the first plurality of parameter sets to generate a second plurality of parameter sets. The parameter-tuning model can be a derivative-free optimization model. In an example, the parameter-tuning model is a PSO model. In some implementations, the PSO model introduces randomness into the second plurality of parameter sets to avoid converging on a local optimum. Parameters of the PSO model can be tuned to modify how the PSO generates parameter sets. Parameters of the PSO model can include a cognitive parameter, a social parameter, inertia weight, and swarm size. Tuning the parameters of the PSO model affect how parameter sets vary between iterations of generating parameter sets. Tuning the parameters of the PSO model can be done to increase an accuracy and/or speed of the PSO model. In an example, the parameters of the PSO model are tuned based on losses between predicted soiling losses and actual soiling losses to increase an accuracy of the PSO model.

In some implementations, the second plurality of parameter sets includes a number of parameter sets equal to the first plurality of parameter sets. In an example, the first plurality of parameter sets includes one hundred parameter sets, the subset includes ten parameter sets, and the second plurality of parameter sets includes one hundred parameter sets. In this way, the parameter-tuning model can iteratively generate improved pluralities of parameter sets using as input subsets of previous pluralities of parameter sets.

In some implementations, the parameter-tuning model is executed using as input the full first plurality of parameter sets and the ranking to generate the second plurality of parameter sets (i.e., without selecting a subset of the first plurality of parameter sets). The first plurality of parameter sets can be weighted according to the ranking. Weighting the first plurality of parameter sets to give much greater weight to a subset of the first plurality of parameter sets than the remaining parameter sets can effectively function as selecting the subset of the first plurality of parameter sets.

In some implementations, the parameter-tuning model is executed using as input the subset of the first plurality of parameter sets and the ranking of the first plurality of parameter sets, or at least the ranking of the subset. The parameter-tuning model can weight the subset according to their ranking, such that parameter sets that cause the PV soiling model to be more accurate are weighted more heavily than parameter sets that cause the PV soiling model to be less accurate.

At operation 660, the PV soiling model is executed with the second plurality of parameter sets using as input the wash data to generate second predicted energy loss data.

At operation 670, a second set of losses is calculated based on a difference between the second predicted energy loss data and the time-series sensor data.

At operation 680, a data structure is generated including a selected parameter set of the second plurality of parameter sets. In some implementations, the data structure is generated in response to a predetermined number of training iterations being completed (i.e., a predetermined number of cycles of generating parameter sets have been performed). In this way, a training time for the parameter set can be constrained. Additionally, computing resources can be conserved, as using a predetermined number of iterations does not require comparing losses to a predetermined error threshold. In an example, the data structure can be generated to include a currently generated parameter set in response to one hundred iterations being performed, as illustrated in FIG. 5.

In some implementations, the data structure is generated in response to a loss of the second set of losses being below a predetermined error threshold, where the selected parameter set corresponds to the loss that is below the predetermined error threshold. In this way, the data structure includes the selected parameter set which caused the PV soiling model to be accurate enough that the loss was below the predetermined error threshold, indicating that the parameter sets have been optimized to meet the predetermined error threshold. In some implementations, the predetermined error threshold is defined as an average absolute difference between the actual soiling losses from the time-series sensor data and predicted energy loss data. In some implementations, the predetermined error threshold is defined as a difference between lowest errors in subsequent pluralities of parameter sets. In an example, if the lowest error for successive pluralities of parameter sets stabilizes (converges), then it is likely that further modification of parameter sets will not decrease the error, and the selected parameter set is selected from the most recent plurality of parameter sets. In an example, FIG. 5 shows how an error of a PV soiling model (losses) executed using successive parameter sets stabilizes after approximately ten iterations.

In some implementations, the selected parameter set includes at least one of a soiling buildup rate, a rain cleaning threshold, a rain accumulation period, and a grace period. An example of a soiling buildup rate generated by a parameter-tuning model is illustrated in FIG. 3. An example of a rain cleaning threshold generated by a parameter-tuning model is illustrated in FIG. 2. In some implementations, the method 600 includes adjusted the soiling buildup rate based on an average soiling buildup rate for a time period. The parameter-tuning model, in generating the second plurality of parameter sets can adjust soiling buildup rate values based on an average soiling buildup rate value across a time period to avoid sharp changes in soiling buildup rate values. In an example, the parameter-tuning model calculates soiling buildup rate values for each month in a year and then adjusts the calculated monthly soiling buildup rate values to reduced changes between successive months.

In some implementations, the method 600 includes generating a recommendation for one or more manual cleaning events by executing the PV soiling model with the selected parameter set using as input modified manual cleaning data. By executing the PV soiling model with the selected parameter set, the error or loss is known, allowing for accurate prediction of an impact of manual cleaning events on PV array output. In an example, the PV soiling model is executed with the selected parameter set using as input five different combinations of cleaning dates to determine which combination of cleaning dates results in the greatest PV array output to determine which combination of cleaning dates to recommend. In some implementations, the method 600 includes generating control signals for an automatic cleaning system to implement the recommendation. In an example, the recommendation is used in a process to generate control signals for an a sprinkler system to clean PV arrays to increase an output of the PV arrays. In some implementations, the recommendation is generated in an iterative process, where a cost of cleaning dates is balanced against increased power output. In an example, a fixed cost is used to determine a number of cleaning dates, and the recommendation is based on a combination of cleaning dates including the number of cleaning dates. In an example, several different numbers of cleaning dates are used to generate recommendations, and the resulting power output increases are compared to the respective cost of the numbers of cleaning dates to determine what number of cleaning dates to use and thus which corresponding set of cleaning dates should be recommended. Factors other than cost and power output may be considered in optimizing the number of cleaning dates.

In some implementations, the method 600 includes executing the PV soiling model with the selected parameter set using as input second wash data to generate third predicted energy loss data and applying the third predicted energy loss data to a prediction of PV array output. The second wash data can include forecasted rainfall data for the location of the PV array. The PV soiling model can be executed using the forecasted rainfall data to predict a future amount of soiling to modify the prediction of future PV array output. In this way, the PV soiling model, with the selected parameter set, can be used to accurately predict how soiling will affect future PV array output, allowing for improved control of renewable energy assets and interventions. In an example, batteries can be controlled to store energy to compensate for a predicted future soiling loss.

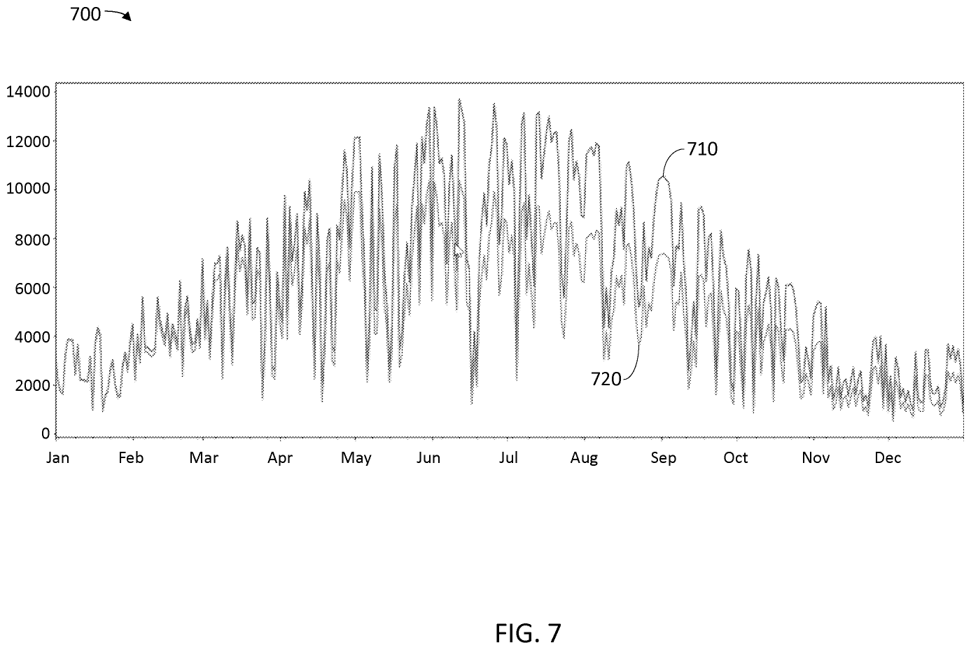

FIG. 7 is an example graph 700 illustrating irradiance 710 and adjusted irradiance 720 modified by soiling losses. The soiling losses are predicted by a PV soiling model, such as the soiling model 160 of FIG. 1. The graph 700 illustrates a scenario where there are no cleaning events. Thus, a percentage difference between the irradiance 710 and the adjusted irradiance 720 due to the soiling losses increases over the course of the year, with absolute differences being larger in months with greater irradiance 710. Thus, the percentage difference between the irradiance 710 and the adjusted irradiance 720 is much lower in the first quarter of the year than in the fourth quarter of the year.

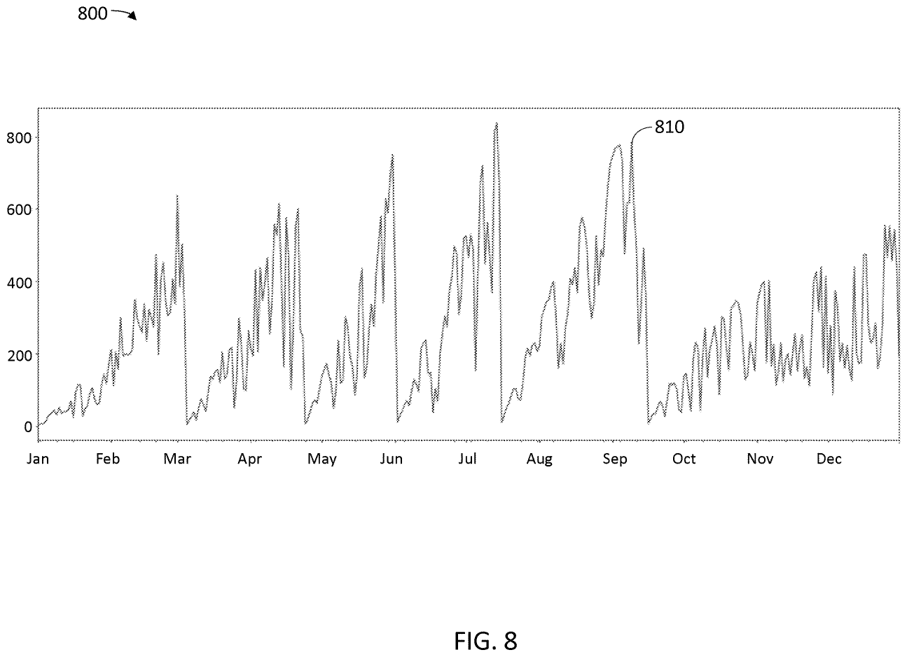

FIG. 8 is an example graph 800 illustrating soiling losses 810. The soiling losses 810 may be the predicted soiling loss causing the difference between the irradiance 710 and the adjusted irradiance 720 of FIG. 7, but with cleaning events added to modify the soiling losses 810. The soiling losses 810 can be modified by executing a PV soiling model using modified wash data. In some implementations, optimal cleaning events can be determined by executing the PV soiling model with different combinations of cleaning events. In an example, determining an optimal single cleaning event for a year can be done by executing the PV soiling model 365 times, with a cleaning event on a different day each time. However, this brute force approach is unfeasible for combinations of cleaning events where the dimensionality of the problem increases. Thus, combinations of three or more cleaning events may require a prohibitive amount of computing resources to optimize.

A much more efficient approach to optimizing cleaning events is to use a cleaning optimization model such as the cleaning optimization model 180 of FIG. 1. As discussed herein, the cleaning optimization model iteratively modifies cleaning events based on predicted soiling losses to determine cleaning events that result in lower predicted soiling losses. The cleaning optimization model can be a PSO model that modifies cleaning events based on results (soiling losses) of prior cleaning events. In this way, the PSO model determines optimal (potentially optimal given the meta-heuristic approach) cleaning events much more efficiently than the brute force approach.

The soiling losses 810 reflect five cleaning events, where the soiling losses 810 are reduced to approximately zero. As discussed above, five cleaning events would be prohibitively compute-intensive to optimize using the brute force approach, potentially requiring several years to compute while using a PSO model to optimize the five cleaning events can be performed in a matter of seconds using the same computing device. Thus, using the PSO model to optimize the cleaning events greatly improves the functioning of the computer by efficiently optimizing the cleaning events to reduce overall soiling losses.

In some implementations, the cleaning optimization model (e.g., PSO model, machine-learning model) is executed using as input a combination of cleaning dates and the soiling losses associated with the cleaning dates to generate a subsequent combination of cleaning dates. In some implementations, the cleaning optimization model is executed using as input a combination of cleaning dates and a score generated using the soiling losses, the score representing an effectiveness of the combination of cleaning dates. The score can reflect relative reduction in soiling losses relative to other combinations of cleaning dates or absolute reduction in soiling losses relative to no cleaning dates. The subsequent combination of cleaning dates can be used as input to the PV soiling model to determine soiling losses associated with the subsequent combination of cleaning dates. The cleaning optimization model can iteratively generate new combinations of cleaning dates to determine an optimal (or relatively optimal) combination of cleaning dates. In some implementations, the cleaning optimization model generates new combinations of cleaning dates until the soiling losses or scores of successive combinations of cleaning dates converge.

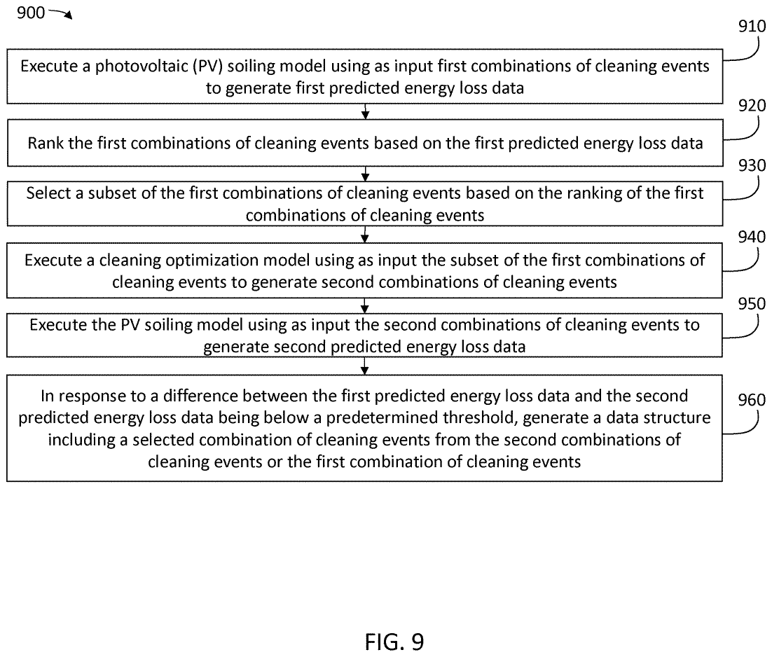

FIG. 9 is a flowchart illustrating operations of an example method 900 for optimizing manual cleaning events. The method 900 may include more, fewer, or different operations than shown. The operations may be performed in the order shown, in a different order, or concurrently. The method 900 may be performed by one or more components of the system 100 of FIG. 1.

At operation 910, a PV soiling model, such as the soiling model 160 of FIG. 1 is executed using as input first combinations of cleaning events to generate first predicted energy loss data (e.g., soiling losses). In an example, the PV soiling model is executed using as input ten different combinations of five cleaning dates. The first combinations of cleaning events may be randomly generated, or generated based on prior combinations of cleaning events.

At operation 920, the first combinations of cleaning events are ranked based on the first predicted energy loss data. The ranking of the first combinations of cleaning events may be used as a score for relative comparison of the first combinations of cleaning events.

At operation 930, a subset of the first combinations of cleaning events is selected based on the ranking of the first combinations of cleaning events. In an example, the first combinations of cleaning events include ten combinations of cleaning events, and the subset includes the best five combinations corresponding to the lowest soiling losses.

At operation 940, a cleaning optimization model is executed using as input the subset of the first combinations of cleaning events to generate second combinations of cleaning events. In some implementations, the cleaning optimization model is executed using as input the subset and the rankings. The cleaning optimization model can weight the combinations of cleaning events of the subset according to the rankings to increase an impact of better combinations of cleaning events that resulted in lower soiling losses on the generation of the second combinations of cleaning events.

In some implementations, the cleaning optimization model is executed using as input the first combinations of cleaning events and the ranking to generate the second combinations of cleaning events without selecting a subset of the first combinations of cleaning events. The first combinations of cleaning events can be weighted according to the ranking. Weighting the first combinations of cleaning events to give much greater weight to a subset of the first combination of cleaning events than the remaining cleaning events can effectively function as selecting the subset of the first combinations of cleaning events.

At operation 950, the PV soiling model is executed using as input the second combinations of cleaning events to generate second predicted energy loss data (soiling losses).

At operation 960, in response to a difference between the first predicted energy loss data and the second predicted energy loss data being below a predetermined threshold, a data structure is generated including a selected combination of cleaning events from the second combinations of cleaning events or the first combination of cleaning events. The difference between the first predicted energy loss data and the second predicted energy loss data being below a predetermined threshold can indicate convergence of the soiling losses. In some implementations, convergence is detected based on a predetermined number of iterations of combinations of cleaning events having predicted energy loss data that do not vary between successive iterations above a predetermined threshold.

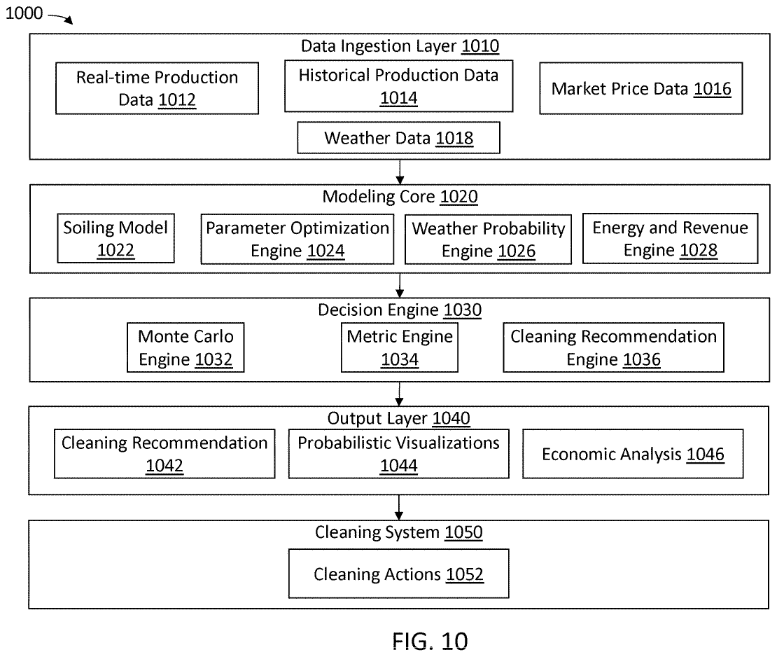

FIG. 10 is a block diagram of an example system 1000 for probabilistic soiling-informed photovoltaic wash optimization. The system 1000 can determine whether and when a photovoltaic site should be cleaned by integrating calibrated soiling models, probabilistic meteorological information, optimization algorithms, and financial evaluation under uncertainty. The system 1000 can generate a plurality of future weather-soiling-production scenarios and compute economic outcomes for both a clean-now case and a do-not-clean case under each scenario. The 1000 system can compute one or more quantitative decision metrics, such as an expected incremental net benefit, a probability of positive benefit, or a wash viability index (WVI). The WVI can be defined as a ratio of expected gross revenue benefit to cleaning cost. The system 1000 can compare the decision metrics to configurable thresholds and output a recommendation to perform or defer cleaning. In some implementations, the system 1000 can generate a recommended cleaning window specifying a timeframe for action. In some implementations, the system 1000 can generate a confidence or risk summary providing probabilistic context for the recommendation. The system 1000 can account for seasonal energy production, providing that cleaning actions are timed relative to high-production and low-production periods to maximize economic benefit. In this way, the system 1000 can increase power output of PV arrays by optimizing the timing of cleaning events to maximize energy recovery while minimizing unnecessary cleaning costs.

The system 1000 includes a data ingestion layer 1010, a modeling core 1020, a decision engine 1030, an output layer 1040, and an optional cleaning system 1050. The data ingestion layer 1010 receives and processes input data for the system 1000. The modeling core 1020 receives data from the data ingestion layer 1010 and performs computational analysis. The decision engine 1030 receives outputs from the modeling core 1020 and generates decision metrics. The output layer 1040 receives outputs from the decision engine 1030 and presents results to users. In some implementations, the system 1000 includes the cleaning system 1050, which receives outputs from the output layer 1040 and implements cleaning actions on photovoltaic modules based on the recommendations generated by the system 1000.

The data ingestion layer 1010 can receive and aggregate data from multiple sources to provide input for the modeling core 1020. The data ingestion layer 1010 includes real-time production data 1012, historical production data 1014, market price data 1016, and weather data 1018. The data ingestion layer 1010 can perform data validation, formatting, or preprocessing operations on the received data prior to providing the data to the modeling core 1020. In some implementations, the data ingestion layer 1010 can synchronize data from different sources to a common time resolution or format. In an example, the data ingestion layer 1010 can resample hourly production data to daily intervals to match the resolution of weather data.

The real-time production data 1012 can include current operational measurements from photovoltaic arrays. The real-time production data 1012 can include instantaneous power output measurements, current irradiance readings, module temperature measurements, or inverter status information, among others. In an example, the real-time production data 1012 can include power output measurements sampled at one-minute intervals from a supervisory control and data acquisition (SCADA) system. The real-time production data 1012 can be received from sensors deployed at a photovoltaic site, such as pyranometers for measuring irradiance, thermocouples for measuring module temperature, or power meters for measuring electrical output. In some implementations, the real-time production data 1012 can include data from soiling sensors that measure current soiling levels on photovoltaic modules.

The real-time production data 1012 can be used by the modeling core 1020 to determine a current soiling state of the photovoltaic array. In an example, the real-time production data 1012 can indicate that current power output is 95% of expected clean-module output, indicating a 5% soiling loss. The real-time production data 1012 can provide a starting point for forward-looking soiling simulations performed by the decision engine 1030. In some implementations, the real-time production data 1012 can be compared against modeled production values to validate or calibrate the soiling model 1022. In an example, a discrepancy between measured production in the real-time production data 1012 and modeled production can trigger recalibration of soiling model parameters by a parameter optimization engine 1024 of the modeling core 1020.

The historical production data 1014 can include past performance records from the photovoltaic site. The historical production data 1014 can span multiple years of operation and can include daily, hourly, or sub-hourly production measurements. In an example, the historical production data 1014 can include five years of hourly energy production records from a utility-scale photovoltaic plant. The historical production data 1014 can include records of past cleaning events, indicating dates when manual or robotic cleaning was performed on the photovoltaic modules. In some implementations, the historical production data 1014 can include maintenance records, outage logs, or equipment degradation information that may affect production levels.

The historical production data 1014 can be used by the parameter optimization engine 1024 to calibrate the soiling model 1022. In an example, the parameter optimization engine 1024 can compare historical measured production against modeled production to estimate site-specific soiling deposition rates, rain cleaning thresholds, or cleaning efficiency coefficients. The historical production data 1014 can provide a basis for validating the accuracy of the soiling model 1022 over extended time periods. In some implementations, the historical production data 1014 can be used to identify seasonal patterns in soiling accumulation or to detect anomalous soiling behavior. In an example, the historical production data 1014 can reveal that soiling accumulation rates are higher during summer months due to increased dust activity in a desert climate.

The market price data 1016 can include energy pricing information for economic evaluation of cleaning decisions. The market price data 1016 can include current spot prices, forward price curves, or contracted power purchase agreement (PPA) rates. In an example, the market price data 1016 can include hourly day-ahead market prices for a regional electricity market. The market price data 1016 can include time-of-use rate schedules that specify different energy values for different hours of the day or seasons of the year. In some implementations, the market price data 1016 can include forecasted price trajectories for the evaluation horizon used by the decision engine 1030.

The market price data 1016 can be used by the energy and revenue engine 1028 to compute the economic value of energy production under different soiling and cleaning scenarios. In an example, the market price data 1016 can indicate that energy produced during afternoon peak hours has a value of $0.15 per kilowatt-hour, while energy produced during overnight hours has a value of $0.05 per kilowatt-hour. The market price data 1016 can enable the system 1000 to weight the economic impact of soiling losses according to when the losses occur relative to high-value and low-value production periods. In some implementations, the market price data 1016 can include capacity payments, renewable energy credits, or other revenue streams that affect the total economic value of photovoltaic production. In an example, the market price data 1016 can include a renewable energy credit value of $0.02 per kilowatt-hour that is added to the energy price when computing revenue impacts of cleaning decisions.

The weather data 1018 can include historical meteorological records and deterministic weather forecasts for the photovoltaic site location. The weather data 1018 can include multi-decade historical rainfall records, temperature measurements, irradiance values, humidity readings, or wind speed measurements, among others. In an example, the weather data 1018 can include twenty-five years of daily rainfall measurements from a regional weather station located within fifteen kilometers of the photovoltaic installation. The weather data 1018 can include short-term deterministic weather forecasts that provide predicted rainfall amounts, temperature values, or irradiance levels for a period of one to fourteen days from a current date. In an example, the weather data 1018 can include a fourteen-day weather forecast obtained from a numerical weather prediction service that specifies expected daily rainfall amounts and temperature ranges.

The weather data 1018 can be used by the weather probability engine 1026 to generate probabilistic future weather trajectories for scenario-based simulations. The weather probability engine 1026 can process the historical meteorological records in the weather data 1018 to estimate probability distributions of rainfall occurrence and magnitude for future time periods. In an example, the weather probability engine 1026 can analyze twenty years of historical rainfall data from the weather data 1018 to determine that rainfall events exceeding five millimeters occur with a probability of 0.15 during a particular week of the year. The weather probability engine 1026 can combine the short-term deterministic forecasts in the weather data 1018 with the long-term historical records to construct synthetic future weather trajectories that incorporate both near-term forecast accuracy and long-term climatological variability. In some implementations, the weather probability engine 1026 can replace a first portion of each synthetic future weather trajectory with data from a current short-term forecast in the weather data 1018, such that near-term weather predictions reflect current forecast information while longer-term weather predictions reflect historical climatological variability.

The modeling core 1020 can receive data from the data ingestion layer 1010 and perform computational analysis for generating cleaning decision recommendations. The modeling core 1020 includes a soiling model 1022, a parameter optimization engine 1024, a weather probability engine 1026, and an energy and revenue engine 1028. The modeling core 1020 can integrate outputs from the soiling model 1022, the weather probability engine 1026, and the energy and revenue engine 1028 to generate inputs for the decision engine 1030. In some implementations, the modeling core 1020 can execute the soiling model 1022, the weather probability engine 1026, and the energy and revenue engine 1028 in a coordinated manner to produce consistent predictions across weather, soiling, and economic dimensions.

The soiling model 1022 can represent temporal degradation of photovoltaic performance due to particulate deposition and natural cleaning events. The soiling model 1022 can receive weather data and cleaning event data as inputs and generate predicted soiling losses as outputs. In an example, the soiling model 1022 can implement a Kimber-type soiling accumulation model in which soiling loss increases between cleaning or rainfall events according to a deposition rate parameter. The soiling model 1022 can model soiling accumulation as a function of time elapsed since a previous cleaning event, a site-specific deposition rate, and rainfall-induced cleaning effects. In some implementations, the soiling model 1022 can incorporate nonlinear or regime-based deposition behavior to account for variations in dust activity across different seasons or weather conditions. The soiling model 1022 can model partial cleaning effects from rainfall events based on rainfall depth and intensity, such that light rainfall may reduce soiling by a smaller percentage than heavy rainfall.

The soiling model 1022 can be configured using site-specific parameters that define soiling accumulation and removal behavior for a particular photovoltaic site. The soiling model 1022 can receive parameters including a soiling deposition rate, a rain cleaning threshold, a rain accumulation period, a grace period, and cleaning efficiency coefficients, among others. In an example, the soiling model 1022 can be configured with a deposition rate of 0.1% per day, a rain cleaning threshold of 5 millimeters, and a rain accumulation period of 24 hours, such that rainfall exceeding 5 millimeters within a 24-hour period triggers a cleaning event that resets soiling to zero. In some implementations, the soiling model 1022 can incorporate seasonal or directional dust effects to account for variations in soiling accumulation rates across different months or wind directions. The soiling model 1022 can generate predicted soiling losses for past, current, or future time periods based on the configured parameters and input weather data.

In some implementations, the soiling model 1022 can implement a soiling accumulation formulation in which soiling loss at time t is expressed as in Expression 0.

S(t)=S₀+r(t−t₀)−ΣᵢΔSᵣₐᵢₙ(i) Expression 0:

In Expression 0, S₀ represents the soiling level at the start of observation, r represents the soiling deposition rate, to represents the initial time, and ΔSᵣₐᵢₙ(i) represents the cleaning effect of the i-th rainfall event. The soiling deposition rate r can be a constant value or can vary seasonally based on site-specific dust activity patterns. The cleaning effect ΔSᵣₐᵢₙ(i) can be modeled as a function of rainfall depth and intensity, such that heavier rainfall events provide greater soiling reduction than lighter rainfall events.

The soiling accumulation formulation of Expression 0 can incorporate nonlinear or regime-based deposition behavior to account for variations in dust activity across different seasons or weather conditions. In some implementations, the soiling model 1022 can apply seasonal or directional dust effects by varying the deposition rate r based on the month of the year or prevailing wind direction. The cleaning effect ΔSᵣₐᵢₙ(i) can incorporate partial or stochastic cleaning efficiencies, such that rainfall events below a rain cleaning threshold provide partial soiling reduction while rainfall events exceeding the rain cleaning threshold reset soiling to zero. In an example, a rainfall event of three millimeters can reduce soiling by fifty percent, while a rainfall event of ten millimeters can reset soiling to zero.

The parameter optimization engine 1024 can calibrate the soiling model 1022 using historical and real-time site data via an optimization algorithm. The parameter optimization engine 1024 can estimate site-specific parameters including deposition rates, rain-induced cleaning thresholds, and cleaning efficiency coefficients. In an example, the parameter optimization engine 1024 can receive five years of historical production data and rainfall measurements and estimate a monthly soiling deposition rate for each month of the year. The parameter optimization engine 1024 can minimize a discrepancy between modeled soiling losses and measured soiling losses by iteratively adjusting soiling model parameters. In some implementations, the parameter optimization engine 1024 can implement a derivative-free optimization algorithm, such as particle swarm optimization (PSO), differential evolution, or Bayesian optimization. The parameter optimization engine 1024 can generate a plurality of candidate parameter sets, evaluate each candidate parameter set by executing the soiling model 1022, and select parameter sets that result in lower prediction errors.

The parameter optimization engine 1024 can correspond to the parameter-tuning model 140 of FIG. 1. The parameter optimization engine 1024 can perform operations similar to the parameter-tuning model 140, including initializing parameter sets, executing the soiling model 1022 with the parameter sets, calculating losses based on differences between predicted and actual soiling losses, ranking the parameter sets based on the calculated losses, and iteratively generating improved parameter sets. In an example, the parameter optimization engine 1024 can initialize one hundred candidate parameter sets with pseudo-random values, execute the soiling model 1022 with each candidate parameter set, calculate an average absolute error between predicted soiling losses and measured soiling losses for each candidate parameter set, rank the candidate parameter sets according to the calculated errors, select the ten candidate parameter sets with lowest errors, and generate a new set of one hundred candidate parameter sets based on the selected subset. The parameter optimization engine 1024 can iterate the optimization process until a loss falls below a predetermined error threshold or a predetermined number of iterations is completed. In some implementations, the parameter optimization engine 1024 can adjust soiling buildup rate values based on an average soiling buildup rate value across a time period to avoid sharp changes in soiling buildup rate values between adjacent months.

The weather probability engine 1026 can process the weather data 1018 to estimate a probability and effectiveness of natural cleaning events. The weather probability engine 1026 can combine long-term historical meteorological data with short-term weather forecasts to produce probabilistic future weather trajectories. In an example, the weather probability engine 1026 can receive twenty years of historical daily rainfall records and a fourteen-day deterministic weather forecast and generate probability distributions of rainfall occurrence and magnitude for future time periods. The weather probability engine 1026 can estimate the probability that rainfall events will reduce soiling below defined thresholds based on historical rainfall statistics. In some implementations, the weather probability engine 1026 can process ensemble weather forecasts that provide multiple possible weather trajectories with associated probabilities. The weather probability engine 1026 can blend short-term forecast data with long-term climatological statistics to account for both near-term weather certainty and long-term weather variability.

The weather probability engine 1026 can generate synthetic future weather trajectories for use in scenario-based simulations performed by the decision engine 1030. The weather probability engine 1026 can construct synthetic weather trajectories using actual historical weather data from a decision date forward, where each historical year provides a distinct weather trajectory representing a possible future weather outcome. In an example, the weather probability engine 1026 can generate twenty synthetic weather trajectories corresponding to twenty historical years, where each synthetic weather trajectory includes daily rainfall amounts, temperature values, and irradiance values for a ninety-day evaluation horizon. In some implementations, the weather probability engine 1026 can replace a first portion of each synthetic weather trajectory with data from a current short-term weather forecast to incorporate near-term forecast accuracy. In an example, the weather probability engine 1026 can replace the first fourteen days of each synthetic weather trajectory with data from a current fourteen-day weather forecast, such that near-term weather predictions reflect current forecast information while longer-term weather predictions reflect historical climatological variability.

The energy and revenue engine 1028 can compute expected energy production and associated revenue over a forward-looking evaluation horizon. The energy and revenue engine 1028 can apply an energy production model that accounts for seasonal irradiance patterns, sun angle, temperature effects, and site-specific performance characteristics. In an example, the energy and revenue engine 1028 can forecast expected photovoltaic generation for a ninety-day evaluation horizon by modeling daily energy production as a function of expected irradiance, module temperature, system efficiency, and soiling losses. The energy and revenue engine 1028 can receive soiling loss predictions from the soiling model 1022 and apply the soiling loss predictions to reduce expected energy production accordingly. In some implementations, the energy and revenue engine 1028 can model temperature-dependent performance degradation, such that higher module temperatures result in lower conversion efficiency.

The energy and revenue engine 1028 can compute the incremental revenue associated with performing a cleaning event at a decision time. The energy and revenue engine 1028 can calculate expected production under clean conditions and expected production under modeled soiling conditions and compute a difference between the expected production values. In an example, the energy and revenue engine 1028 can determine that expected production under clean conditions for a ninety-day evaluation horizon is 500 megawatt-hours, while expected production under modeled soiling conditions is 475 megawatt-hours, resulting in an incremental energy gain of 25 megawatt-hours from cleaning. The energy and revenue engine 1028 can apply energy prices from the market price data 1016 to convert incremental energy gains to incremental revenue gains. In some implementations, the energy and revenue engine 1028 can apply time-varying energy prices to weight the economic impact of soiling losses according to when the losses occur relative to high-value and low-value production periods. In an example, the energy and revenue engine 1028 can determine that 15 megawatt-hours of the incremental energy gain occurs during peak hours at $0.15 per kilowatt-hour and 10 megawatt-hours occurs during off-peak hours at $0.05 per kilowatt-hour, resulting in an incremental revenue gain of $2,750.

The decision engine 1030 can receive outputs from the modeling core 1020 and generate decision metrics for cleaning recommendations. The decision engine 1030 includes a Monte Carlo Engine 1032, a metric engine 1034, and a cleaning recommendation engine 1036. The decision engine 1030 can coordinate the Monte Carlo Engine 1032, the metric engine 1034, and the cleaning recommendation engine 1036 to produce probabilistic cleaning recommendations based on scenario-based simulations. In some implementations, the decision engine 1030 can execute the Monte Carlo Engine 1032 to generate multiple future weather-soiling-production scenarios, execute the metric engine 1034 to compute quantitative decision metrics from the scenario results, and execute the cleaning recommendation engine 1036 to generate actionable cleaning recommendations based on the computed metrics.

The Monte Carlo Engine 1032 can generate a plurality of future weather-soiling-production scenarios and compute economic outcomes for different cleaning decisions under each scenario. The Monte Carlo Engine 1032 can send requests to the modeling core 1020 for weather-soiling-production predictions corresponding to various scenarios. In an example, the Monte Carlo Engine 1032 can send a request to the weather probability engine 1026 for a synthetic weather trajectory corresponding to a particular historical year, receive the synthetic weather trajectory, and send a subsequent request to the soiling model 1022 for predicted soiling losses based on the synthetic weather trajectory. The Monte Carlo Engine 1032 can iterate over multiple historical years to generate a distribution of possible future outcomes. In some implementations, the Monte Carlo Engine 1032 can send requests to the energy and revenue engine 1028 for expected energy production and revenue calculations based on the predicted soiling losses from each scenario.

The Monte Carlo Engine 1032 can evaluate two scenarios for each historical year of long-term historical meteorological data: a first scenario in which a candidate manual cleaning event occurs at a decision time and a second scenario in which no manual cleaning event occurs at the decision time. The Monte Carlo Engine 1032 can send a first request to the modeling core 1020 for a weather-soiling-production prediction under clean conditions and a second request to the modeling core 1020 for a weather-soiling-production prediction under soiled conditions. In an example, the Monte Carlo Engine 1032 can send a request to the soiling model 1022 specifying that a cleaning event occurs on a decision date, receive predicted soiling losses that start at zero on the decision date and accumulate thereafter, and send a corresponding request to the energy and revenue engine 1028 for expected production under the clean scenario. The Monte Carlo Engine 1032 can compute an incremental benefit of cleaning for each historical year by calculating a difference between revenue of the first scenario and revenue of the second scenario minus a cleaning cost using the energy and revenue engine 1028. In some implementations, the Monte Carlo Engine 1032 can store the incremental benefit values for each historical year in a data structure for subsequent processing by the metric engine 1034.

The metric engine 1034 can compute quantitative decision metrics from the scenario results generated by the Monte Carlo Engine 1032. The metric engine 1034 can receive a set of incremental benefit values corresponding to multiple historical years and compute statistical measures of the incremental benefit distribution. In an example, the metric engine 1034 can receive twenty incremental benefit values corresponding to twenty historical years and compute an expected incremental net benefit as an average of the twenty incremental benefit values. The metric engine 1034 can compute a probability that cleaning yields a positive benefit by calculating a proportion of the incremental benefit values that exceed zero. In some implementations, the metric engine 1034 can compute distribution percentiles, such as P10, P50, or P90 percentiles, to quantify downside and upside risk associated with cleaning decisions.

The metric engine 1034 can compute a wash viability index (WVI) defined as a ratio of expected gross revenue benefit to cleaning cost. The metric engine 1034 can receive an expected gross revenue benefit from the scenario results and a cleaning cost from the data ingestion layer 1010 and compute the WVI by dividing the gross revenue benefit by the cleaning cost. In an example, the metric engine 1034 can determine that gross revenue benefit is $3,000 and a cleaning cost is $2,000, resulting in a WVI of 1.5, indicating that expected gains exceed cleaning cost. The WVI can be evaluated using configurable thresholds, such that a WVI greater than 1 indicates a strong recommendation to clean, a WVI between 0 and 1 indicates marginal or uncertain benefit, and a WVI less than or equal to 0 indicates expected net loss. In some implementations, the metric engine 1034 can compute additional decision metrics, such as a probability-weighted net present value (NPV) that discounts future revenues using a time-value-of-money factor.

The cleaning recommendation engine 1036 can compare the decision metrics to the configurable thresholds and generate cleaning recommendations. The cleaning recommendation engine 1036 can receive the WVI, the probability of positive benefit, and the distribution percentiles from the metric engine 1034 and apply decision rules to generate a recommendation to perform or defer cleaning. In an example, the cleaning recommendation engine 1036 can receive a WVI of 1.5 and a probability of positive benefit of 0.85, compare the WVI to a threshold of 1.0 and the probability to a threshold of 0.7, and generate a recommendation to perform cleaning based on both metrics exceeding the respective thresholds. In some implementations, the cleaning recommendation engine 1036 can incorporate risk tolerance parameters, such that the cleaning recommendation engine 1036 requires a minimum probability of positive benefit or a capped downside loss at a specified percentile before recommending cleaning.

The cleaning recommendation engine 1036 can generate a recommended cleaning window specifying a timeframe for action. The recommended cleaning window can correspond to a decision time of a scenario evaluated by the Monte Carlo Engine 1032. In some implementations, the recommended cleaning window can correspond to a cluster of decision times that yield net-positive outcomes across the plurality of cleaning event scenarios. In an example, the cleaning recommendation engine 1036 can identify multiple decision times within a seven-day period that each produce positive incremental benefit values across a majority of historical years, and the cleaning recommendation engine 1036 can aggregate the multiple decision times into a single recommended cleaning window spanning the seven-day period.

The cleaning recommendation engine 1036 can generate a confidence or risk summary providing probabilistic context for the recommendation. The cleaning recommendation engine 1036 can include information regarding the probability of positive benefit, the expected incremental net benefit, and the distribution percentiles in the confidence or risk summary. In an example, the cleaning recommendation engine 1036 can generate a recommendation to wash within the next seven days with a confidence summary indicating a 75% chance of positive benefit and an expected incremental net benefit of $2,500. In some implementations, the cleaning recommendation engine 1036 can calculate an expected value of cleaning by multiplying the probability of positive benefit by the expected incremental net benefit. In an example, the cleaning recommendation engine 1036 can determine that a probability of positive benefit is 0.80 and an expected incremental net benefit is $3,000, resulting in an expected value of $2,400 for performing the cleaning event.

The cleaning recommendation engine 1036 can generate a clean recommendation, a defer recommendation, or a re-evaluate date window recommendation based on comparison of decision metrics to configurable thresholds. The cleaning recommendation engine 1036 can compare the WVI to an upper threshold and a lower threshold to determine the recommendation type. In an example, the cleaning recommendation engine 1036 can receive a WVI and compare the WVI to an upper threshold of 1.2 and a lower threshold of 0.8. In response to the WVI exceeding the upper threshold, the cleaning recommendation engine 1036 can generate a clean recommendation indicating that the expected economic benefit of cleaning substantially exceeds the cleaning cost. In response to the WVI falling below the lower threshold, the cleaning recommendation engine 1036 can generate a defer recommendation indicating that the expected economic benefit of cleaning does not justify the cleaning cost under current conditions. In response to the WVI falling between the upper threshold and the lower threshold, the cleaning recommendation engine 1036 can generate a re-evaluate date window recommendation indicating that the cleaning decision is marginal and should be reassessed for an alternative timeframe.

The re-evaluate date window recommendation can involve evaluating another date window at the present time to determine whether a different cleaning timeframe yields a more favorable economic outcome. In some implementations, the cleaning recommendation engine 1036 can trigger the Monte Carlo Engine 1032 to generate additional cleaning event scenarios corresponding to one or more alternative decision times. In an example, the cleaning recommendation engine 1036 can receive a WVI of 1.0 for a first decision time, determine that the WVI falls between the upper threshold of 1.2 and the lower threshold of 0.8, and request the Monte Carlo Engine 1032 to evaluate scenarios for a second decision time occurring seven days after the first decision time. The cleaning recommendation engine 1036 can compare the WVI values for the first decision time and the second decision time to identify a decision time that yields a WVI exceeding the upper threshold. In some implementations, the cleaning recommendation engine 1036 can evaluate multiple alternative date windows in parallel to identify an optimal cleaning timeframe. In an example, the cleaning recommendation engine 1036 can evaluate date windows at seven-day intervals over a thirty-day horizon and select the date window having the highest WVI for the cleaning recommendation 1042.

The cleaning recommendation engine 1036 can provide the cleaning recommendation 1042 to the output layer 1040 for presentation to users or for transmission to the cleaning system 1050. The output layer 1040 can receive outputs from the decision engine 1030 and present results to users or external systems. The output layer 1040 includes the cleaning recommendation 1042, probabilistic visualizations 1044, and economic analysis 1046. The output layer 1040 can format the outputs from the decision engine 1030 for display on user interfaces, for storage in data structures, or for transmission to downstream systems such as the cleaning system 1050.

The cleaning recommendation 1042 can include actionable guidance on whether to perform or defer a cleaning event on the photovoltaic array. The cleaning recommendation 1042 can specify a recommendation action, such as a wash now action, a defer action, or a re-evaluate action, among others. In an example, the cleaning recommendation 1042 can indicate that a cleaning event should be performed within a specified timeframe, such as within the next seven days. In an example, the cleaning recommendation 1042 can indicate that a cleaning event should be deferred until a subsequent evaluation date when updated weather forecasts and soiling conditions can be reassessed. The cleaning recommendation 1042 can include a recommended cleaning window specifying a timeframe for action. In an example, the recommended cleaning window can specify that cleaning should occur between a first date and a second date to maximize economic benefit based on the probabilistic analysis performed by the decision engine 1030.

The cleaning recommendation 1042 can include a confidence or risk summary providing probabilistic context for the recommendation. In an example, the confidence or risk summary can indicate a probability of positive benefit, such as a 75% chance that the cleaning event will yield a positive economic return. In an example, the confidence or risk summary can indicate an expected incremental net benefit, such as an expected revenue gain of $2,500 from performing the cleaning event. The cleaning recommendation 1042 can be formatted as a data structure for transmission to the cleaning system 1050, or as a human-readable message for display on a user interface. In some implementations, the cleaning recommendation 1042 can include a re-evaluation date when the recommendation is to defer cleaning, such that the system 1000 can reassess the cleaning decision at a future time based on updated weather forecasts and soiling conditions.

The probabilistic visualizations 1044 can display uncertainty and risk information associated with the cleaning decision. The probabilistic visualizations 1044 can include graphical representations of the distribution of possible economic outcomes across the plurality of cleaning event scenarios generated by the Monte Carlo Engine 1032. In an example, the probabilistic visualizations 1044 can include a histogram displaying the distribution of incremental benefit values across multiple historical years, such that a user can observe the range of possible outcomes and the likelihood of each outcome. In an example, the probabilistic visualizations 1044 can include a cumulative distribution function plot displaying the probability that the incremental benefit exceeds various threshold values. The probabilistic visualizations 1044 can include visual indicators of distribution percentiles, such as P10, P50, or P90 percentiles, to quantify downside and upside risk associated with cleaning decisions.

The probabilistic visualizations 1044 can include time-series plots displaying predicted soiling losses under different weather scenarios. In an example, the probabilistic visualizations 1044 can display a fan chart showing the range of possible soiling trajectories over a forward-looking evaluation horizon, with confidence bands indicating the uncertainty in the soiling predictions. In an example, the probabilistic visualizations 1044 can display a comparison of expected energy production under clean conditions and expected energy production under soiled conditions across multiple scenarios. The probabilistic visualizations 1044 can include interactive elements that allow users to explore different scenarios or adjust configurable thresholds. In some implementations, the probabilistic visualizations 1044 can include color-coded indicators that visually represent the wash viability index (WVI) or the probability of positive benefit, such that users can quickly assess the strength of the cleaning recommendation.

The economic analysis 1046 can provide financial justification summaries for the cleaning recommendation. The economic analysis 1046 can include detailed breakdowns of the expected incremental revenue, the cleaning cost, and the net economic benefit associated with performing a cleaning event. In an example, the economic analysis 1046 can indicate that expected production under clean conditions for a ninety-day evaluation horizon is 500 megawatt-hours, expected production under soiled conditions is 475 megawatt-hours, and the incremental energy gain from cleaning is 25 megawatt-hours. In an example, the economic analysis 1046 can indicate that the incremental energy gain translates to an incremental revenue gain of $3,000 based on energy prices from the market price data 1016, and that the cleaning cost is $2,000, resulting in a net economic benefit of $1,000. The economic analysis 1046 can include the wash viability index (WVI) computed by the metric engine 1034, such as a WVI of 1.5 indicating that expected gains exceed cleaning cost by a factor of 1.5.

The economic analysis 1046 can include time-varying revenue impacts that account for seasonal energy production and time-of-use pricing. In an example, the economic analysis 1046 can indicate that 15 megawatt-hours of the incremental energy gain occurs during peak hours at $0.15 per kilowatt-hour and 10 megawatt-hours occurs during off-peak hours at $0.05 per kilowatt-hour, resulting in a weighted incremental revenue gain of $2,750. In an example, the economic analysis 1046 can indicate that cleaning during a high-production season yields a higher economic benefit than cleaning during a low-production season due to the greater energy recovery during periods of higher irradiance. The economic analysis 1046 can include sensitivity analyses showing how the net economic benefit varies with changes in cleaning cost, energy prices, or soiling model parameters. In some implementations, the economic analysis 1046 can include a probability-weighted net present value (NPV) that discounts future revenues using a time-value-of-money factor, such that the economic analysis 1046 accounts for the timing of revenue recovery relative to the cleaning event.

The cleaning system 1050 can receive the cleaning recommendation 1042 from the output layer 1040 and implement cleaning actions 1052 on the photovoltaic array. The cleaning actions 1052 can include commands transmitted to a cleaning scheduling system to implement manual cleaning events based on the recommendations generated by the system 1000. The cleaning actions 1052 can specify a cleaning date, a cleaning time window, and a set of photovoltaic modules to be cleaned. In some implementations, the cleaning actions 1052 can include control signals transmitted to automated cleaning equipment to initiate cleaning operations without human intervention. In an example, an automated cleaning system can receive the cleaning actions 1052 and activate sprinklers positioned above the photovoltaic modules to spray water across module surfaces, or deploy robotic cleaning arms that traverse the photovoltaic array and remove accumulated particulate matter from module surfaces. The cleaning actions 1052 can include parameters specifying cleaning intensity, duration, or coverage area based on the soiling level predicted by the soiling model 1022.

In some implementations, the cleaning actions 1052 can include task generation for implementation by personnel or automated systems. In an example, the cleaning scheduling system can receive the cleaning actions 1052 and generate work orders or task assignments for maintenance personnel to perform manual cleaning of the photovoltaic modules within the recommended cleaning window. The cleaning scheduling system can allocate resources, schedule labor, or coordinate equipment availability based on the cleaning actions 1052. In some implementations, the cleaning scheduling system can prioritize cleaning tasks across multiple photovoltaic sites based on the WVI values or expected incremental net benefits computed by the metric engine 1034 for each site. The cleaning actions 1052 can include confirmation requests or completion acknowledgments that the cleaning system 1050 transmits back to the system 1000, such that the system 1000 can update the soiling model 1022 with records of completed cleaning events for subsequent scenario evaluations.

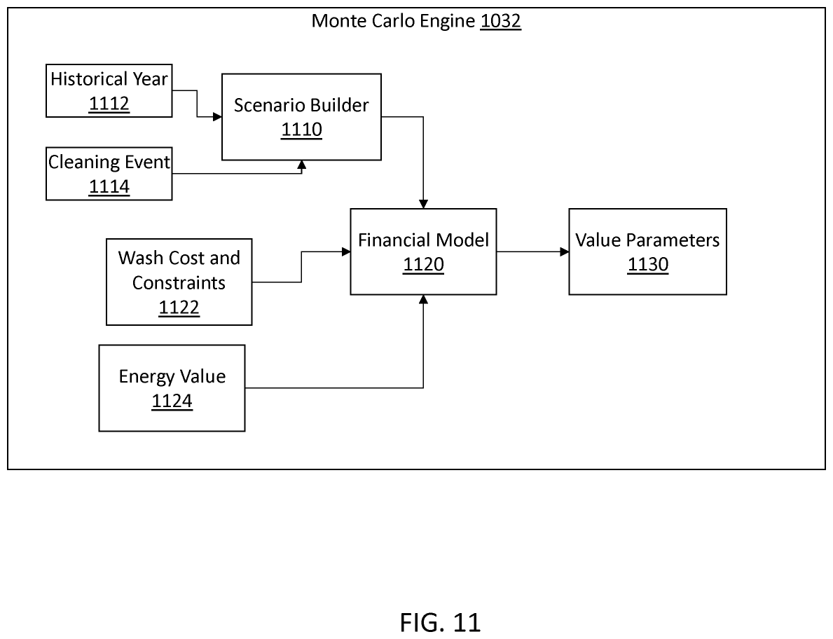

FIG. 11 is a block diagram of the Monte Carlo Engine 1032 of FIG. 10. The Monte Carlo Engine 1032 includes a scenario builder 1110 which provides scenarios and their characteristics to a Financial Model 1120 to generate Value Parameters 1130.

The scenario builder 1110 can receive as input a Historical Year 1112 and a Cleaning Event 1114 to generate a scenario for evaluation by the Financial Model 1120. The Historical Year 1112 can specify a particular year from long-term historical meteorological data, such as a year selected from twenty or more years of historical weather records. The Cleaning Event 1114 can specify whether a candidate manual cleaning event occurs at a decision time or whether no manual cleaning event occurs at the decision time. The scenario builder 1110 can generate scenarios for each historical year of the long-term historical meteorological data, such that the Monte Carlo Engine 1032 evaluates multiple possible future weather outcomes based on historical climate variability.

For the Historical Year 1112 (and each historical year used to generate a scenario), the scenario builder 1110 can construct a synthetic future weather trajectory using actual historical weather data from a decision date forward. In an example, the scenario builder 1110 can receive a Historical Year 1112 corresponding to the year 2015 and construct a synthetic future weather trajectory by extracting daily rainfall measurements, temperature readings, and irradiance values from the historical weather records for 2015 starting from a decision date of March 15 and extending forward for ninety days through June 13. The synthetic future weather trajectory can include daily rainfall amounts, temperature values, or irradiance values for an evaluation horizon (e.g., sixty to one hundred twenty days). In some implementations, the scenario builder 1110 can replace a first portion of the synthetic future weather trajectory (e.g., fourteen days) with data from a current short-term weather forecast, such that near-term weather predictions reflect current forecast information while longer-term weather predictions reflect historical climatological variability.

The scenario builder 1110 can provide each synthetic weather trajectory as input to the soiling model 1022 and the energy and revenue engine 1028. The soiling model 1022 can generate predicted soiling losses based on the synthetic weather trajectory and the Cleaning Event 1114. The energy and revenue engine 1028 can generate seasonally varying production forecasts and for each scenario year based on the synthetic weather trajectory and the predicted soiling losses. In an example, the energy and revenue engine 1028 can account for variations in solar irradiance, day length, sun angle, or temperature-dependent performance across different months of the evaluation horizon.

The scenario builder 1110 can generate two distinct predicted output values for each scenario corresponding to a given Historical Year 1112: a first predicted output value representing expected energy production when the Cleaning Event 1114 occurs at the decision time, and a second predicted output value representing expected energy production when no cleaning event occurs at the decision time. The scenario builder 1110 can execute the soiling model 1022 twice for each Historical Year 1112, with a first execution specifying that a cleaning event resets soiling to zero at the decision time and a second execution specifying that soiling continues to accumulate from the current soiling level without intervention. In an example, the scenario builder 1110 can generate a first predicted output of 500 megawatt-hours for a ninety-day evaluation horizon under clean conditions and a second predicted output of 475 megawatt-hours for the same evaluation horizon under soiled conditions. The scenario builder 1110 can provide the first predicted output and the second predicted output to the Financial Model 1120 for economic evaluation of the incremental benefit of cleaning.

The Financial Model 1120 can receive the first predicted output and the second predicted output from the scenario builder 1110, along with Wash Cost and Constraints 1122 and Energy Value 1124. The Financial Model 1120 can compute an incremental energy gain by calculating a difference between the first predicted output and the second predicted output. The Financial Model 1120 can apply the Energy Value 1124 to convert the incremental energy gain to an incremental revenue gain. The Financial Model 1120 can subtract the Wash Cost and Constraints 1122 from the incremental revenue gain to compute a net economic benefit for the scenario. In an example, the Financial Model 1120 can receive a first predicted output of 500 megawatt-hours, a second predicted output of 475 megawatt-hours, an energy value of $100 per megawatt-hour, and a wash cost of $2,000, and compute a net economic benefit of $500 (i.e., 25 megawatt-hours multiplied by $100 per megawatt-hour minus $2,000). The Financial Model 1120 can output the Value Parameters 1130, which can include the incremental revenue gain, the net economic benefit, or other economic metrics for the scenario corresponding to the Historical Year 1112.

In some implementations, the Financial Model 1120 can receive incremental revenue calculations directly from the energy and revenue engine 1028 rather than receiving the Energy Value 1124 as a separate input. The energy and revenue engine 1028 can apply time-varying energy prices to the first predicted output and the second predicted output to compute the incremental revenue gain from cleaning, and the energy and revenue engine 1028 can provide the computed incremental revenue gain to the Financial Model 1120 for subtraction of the Wash Cost and Constraints 1122 to determine the net economic benefit.

In some implementations, the Energy Value 1124 can be adjusted for inflation to convert future revenue values to present-value dollars, such that the Financial Model 1120 accounts for the change in real value over time in evaluating current cleaning actions. In some implementations, the Energy Value 1124 can use recent energy prices rather than historical energy prices to account for changes in energy market conditions over time while still incorporating seasonal variation patterns derived from historical data. In an example, the Energy Value 1124 can scale historical seasonal price patterns by a ratio of current average energy prices to historical average energy prices, such that the Financial Model 1120 reflects current market conditions while preserving the relative price differences between peak and off-peak periods or between high-production and low-production seasons.

In some implementations, the Financial Model 1120 can discount future revenues using a time-value-of-money factor to compute a probability-weighted net present value (NPV). The Financial Model 1120 can apply a discount rate to future revenue values to convert the future revenue values to present-value equivalents. In an example, the Financial Model 1120 can receive a discount rate of 5% per annum and apply the discount rate to incremental revenue gains occurring at various points within the evaluation horizon, such that revenue gains occurring later in the evaluation horizon are weighted less heavily than revenue gains occurring earlier in the evaluation horizon. The Financial Model 1120 can compute the NPV by summing the discounted incremental revenue values across the evaluation horizon and subtracting the Wash Cost and Constraints 1122. In some implementations, the Financial Model 1120 can weight the NPV values from each scenario corresponding to each Historical Year 1112 by a probability associated with the scenario to compute a probability-weighted NPV. In an example, the Financial Model 1120 can assign equal probability weights to each of twenty historical years, compute the NPV for each historical year, and calculate a weighted average of the NPV values to obtain an expected NPV that accounts for uncertainty in future weather outcomes. The probability-weighted NPV can provide a risk-adjusted measure of the economic benefit of cleaning that accounts for both the timing of revenue recovery and the variability of weather-driven soiling outcomes.

In some implementations, the Financial Model 1120 can compute the incremental revenue associated with performing a cleaning event at a decision time t. The Financial Model 1120 can evaluate an integral over an evaluation horizon T to determine the incremental revenue ΔR(t). The incremental revenue can be expressed as in Expression 1:

$$Δ R ( t ) = {\int }_{t}^{t + T} [ {E}_{clean} ( {t}^{′} ) - {E}_{soiled} ( {t}^{′} ) ] P ( {t}^{′} ) {dt}^{′} \qquad Expression 1$$

In Expression 1, E_{clean}(t′) represents expected production under clean conditions, E_{soiled}(t′) represents expected production under modeled soiling conditions, P(t′) represents an energy price forecast at time t′, and T represents the evaluation horizon. The Financial Model 1120 can compute a net economic benefit B(t) by subtracting the cleaning cost from the incremental revenue as in Expression 2.

B(t)=ΔR(t)−C_{wash} Expression 2:

In Expression 2, C_{wash} corresponds to the Wash Cost and Constraints 1122. In an example, the Financial Model 1120 can receive an evaluation horizon of ninety days, compute the difference between clean and soiled production for each day of the evaluation horizon, multiply each daily difference by a corresponding energy price from the Energy Value 1124, sum the daily revenue differences to obtain the incremental revenue ΔR(t), and subtract the wash cost to obtain the net economic benefit B(t) for inclusion in the Value Parameters 1130.

The Financial Model 1120 can generate the Value Parameters 1130 including an expected incremental net benefit, a probability that cleaning yields a positive benefit, and distribution percentiles to quantify downside and upside risk. The Financial Model 1120 can compute the expected incremental net benefit by calculating an average of the net economic benefit values across the plurality of scenarios corresponding to the plurality of historical years. In an example, the Financial Model 1120 can receive net economic benefit values from twenty scenarios corresponding to twenty historical years and compute the expected incremental net benefit as an arithmetic mean of the twenty net economic benefit values. The Financial Model 1120 can compute the probability that cleaning yields a positive benefit by determining a proportion of the net economic benefit values that exceed zero. In an example, the Financial Model 1120 can determine that fifteen of twenty net economic benefit values are positive, resulting in a probability of positive benefit of 0.75. The Financial Model 1120 can compute distribution percentiles, such as P10, P50, or P90 percentiles, by sorting the net economic benefit values and identifying values at specified positions within the sorted distribution. In an example, the Financial Model 1120 can compute a P10 percentile representing a downside risk scenario in which only ten percent of outcomes are worse, a P50 percentile representing a median outcome, and a P90 percentile representing an upside scenario in which ninety percent of outcomes are worse. The distribution percentiles can quantify the range of possible economic outcomes and provide risk indicators for the cleaning decision. The Financial Model 1120 can include the expected incremental net benefit, the probability of positive benefit, and the distribution percentiles in the Value Parameters 1130 for subsequent processing by the metric engine 1034.

In some implementations, the Value Parameters 1130 can include the wash viability index (WVI) that quantifies the economic attractiveness of a cleaning decision relative to the cleaning cost. The Financial Model 1120 can compute the WVI as a ratio of the expected gross revenue benefit to the cleaning cost. The WVI can be expressed as in Expression 3:

$$W V I = \frac{𝔼 [ Δ R ]}{{C}_{wash}} \qquad Expression 3$$

In Expression 3, [symbol] [ΔR] represents the expected gross revenue benefit computed across the plurality of scenarios corresponding to the plurality of historical years, and C_{wash} represents the cleaning cost from the Wash Cost and Constraints 1122. The Financial Model 1120 can evaluate the WVI to determine a strength of the cleaning recommendation. In an example, a WVI greater than 1 can indicate that expected gains exceed the cleaning cost, resulting in a strong recommendation to clean. In an example, a WVI between 0 and 1 can indicate marginal or uncertain benefit from cleaning. In an example, a WVI less than or equal to 0 can indicate an expected net loss, resulting in a recommendation to defer cleaning. The Financial Model 1120 can include the WVI in the Value Parameters 1130 for subsequent processing by the metric engine 1034 and the cleaning recommendation engine 1036.

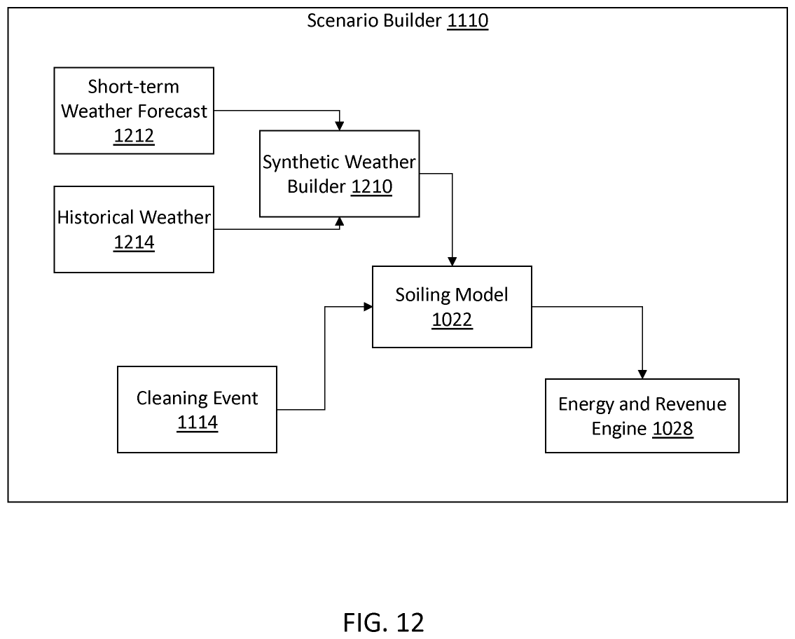

FIG. 12 is a block diagram of the scenario builder 1110 of FIG. 11. The scenario builder 1110 includes a synthetic weather builder 1210 that receives input from a short-term weather forecast 1212 and Historical Weather 1214. The synthetic weather builder 1210 can combine the short-term weather forecast 1212 and the Historical Weather 1214 to generate probabilistic future weather trajectories for use in scenario-based simulations performed by the Monte Carlo Engine 1032.

The Historical Weather 1214 can include multi-decade historical rainfall records spanning twenty or more years of meteorological observations. The synthetic weather builder 1210 can process the Historical Weather 1214 to estimate probability distributions of rainfall occurrence and magnitude by future time period. In an example, the synthetic weather builder 1210 can analyze the Historical Weather 1214 to determine that rainfall events exceeding five millimeters occur with a probability of 0.15 during a particular week of the year based on twenty years of historical observations. The synthetic weather builder 1210 can process the Historical Weather 1214 to estimate the probability that rainfall events will reduce soiling below defined thresholds. In an example, the synthetic weather builder 1210 can determine from the Historical Weather 1214 that rainfall events sufficient to trigger a cleaning effect (e.g., exceeding a rain cleaning threshold) occur with a probability of 0.25 during a thirty-day evaluation window based on historical rainfall patterns.

The short-term weather forecast 1212 can include high-resolution weather forecasts that provide deterministic rainfall predictions for the near term. In an example, the short-term weather forecast 1212 can include daily rainfall predictions for a period of one to fourteen days from a decision date. The short-term weather forecast 1212 can include ensemble-based probabilities of significant cleaning rainfall derived from multiple forecast model runs. In an example, the short-term weather forecast 1212 can indicate a 60% probability of rainfall exceeding ten millimeters within the next seven days based on an ensemble of weather forecast models.

The synthetic weather builder 1210 can blend the short-term weather forecast 1212 with the Historical Weather 1214 to produce probabilistic future weather trajectories that incorporate both near-term forecast accuracy and long-term climatological variability. In some implementations, the synthetic weather builder 1210 can replace a first portion of each synthetic future weather trajectory (e.g., fourteen days) with data from the short-term weather forecast 1212, such that near-term weather predictions reflect current forecast information while longer-term weather predictions reflect historical climatological variability from the Historical Weather 1214. The synthetic weather builder 1210 can provide the generated probabilistic future weather trajectories to the soiling model 1022 for prediction of soiling losses under each weather scenario.

The soiling model 1022 can receive the probabilistic future weather trajectories from the synthetic weather builder 1210 and the Cleaning Event 1114 to generate predicted soiling losses for each scenario. The soiling model 1022 can apply the probabilistic future weather trajectories to determine when rainfall events occur and whether the rainfall events exceed a rain cleaning threshold sufficient to reduce soiling on photovoltaic modules. The soiling model 1022 can incorporate the Cleaning Event 1114 to model the effect of a candidate manual cleaning event on the soiling state, such that the soiling model 1022 generates a first set of predicted soiling losses corresponding to a scenario in which the Cleaning Event 1114 occurs at a decision time and a second set of predicted soiling losses corresponding to a scenario in which no manual cleaning event occurs. In an example, the soiling model 1022 can receive a probabilistic future weather trajectory indicating rainfall events on specific days within an evaluation horizon and generate predicted soiling losses that decrease in response to rainfall events exceeding the rain cleaning threshold and increase between rainfall events according to a site-specific deposition rate. The energy and revenue engine 1028 can receive the probabilistic future weather trajectories from the synthetic weather builder 1210 and the predicted soiling losses from the soiling model 1022 to generate predicted power output and predicted revenue for each scenario. The energy and revenue engine 1028 can apply an energy production model that accounts for seasonal irradiance patterns, sun angle, or temperature effects, among others, to forecast expected photovoltaic generation over the evaluation horizon. The energy and revenue engine 1028 can reduce the expected photovoltaic generation by the predicted soiling losses to compute expected production under soiled conditions. In an example, the energy and revenue engine 1028 can determine that expected production under clean conditions for a ninety-day evaluation horizon is 500 megawatt-hours and apply predicted soiling losses from the soiling model 1022 to compute expected production under soiled conditions of 475 megawatt-hours. The energy and revenue engine 1028 can apply energy prices to the expected production values to compute predicted revenue for each scenario, such that the predicted revenue reflects both the weather-driven soiling outcomes and the seasonal variation in energy production.

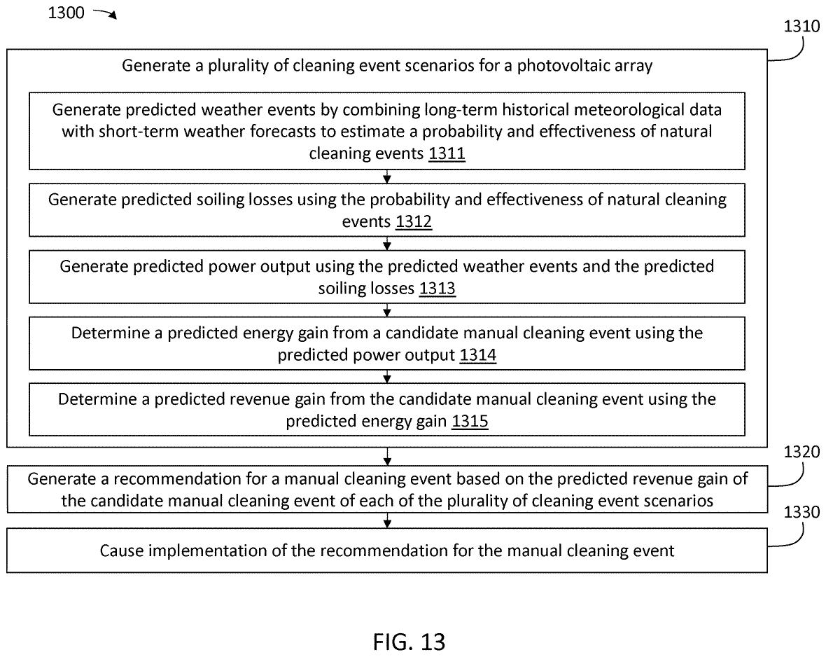

FIG. 13 is a flowchart illustrating operations of an example method 1300 for optimizing manual cleaning events based on probabilistic weather predictions. The method 1300 may include more, fewer, or different operations than shown. One or more operations may be performed in the order shown, in a different order, and/or concurrently. The method 1300 may be performed by one or more components of the system 1000 of FIG. 10.

At operation 1310, a plurality of cleaning event scenarios are generated for a photovoltaic array. The plurality of cleaning event scenarios can represent different possible future weather-soiling-production outcomes based on historical climate variability and current weather forecasts. In an example, twenty cleaning event scenarios can be generated corresponding to twenty historical years of meteorological data, where each cleaning event scenario represents a distinct possible future weather trajectory and associated soiling and production outcomes. Operations 1311-1315 are sub-operations of operation 1310.

At operation 1311, predicted weather events are generated by combining long-term historical meteorological data with short-term weather forecasts to estimate a probability and effectiveness of natural cleaning events. The long-term historical meteorological data can span twenty or more years of rainfall records, temperature measurements, or irradiance values, among others. The short-term weather forecasts can include deterministic rainfall predictions for a period of one to fourteen days from a decision date. In an example, predicted weather events can be generated by analyzing twenty years of historical rainfall data to determine probability distributions of rainfall occurrence and magnitude, and combining the probability distributions with a fourteen-day weather forecast to produce probabilistic future weather trajectories.

In some implementations, generating the predicted weather events can include constructing synthetic future weather trajectories using actual historical weather data from a decision date forward. Each synthetic future weather trajectory can correspond to a particular historical year and can include daily rainfall amounts, temperature values, or irradiance values for an evaluation horizon. In an example, a synthetic future weather trajectory can be constructed by extracting daily rainfall measurements from historical weather records for a particular year starting from a decision date of March 15 and extending forward for ninety days through June 13.

In some implementations, constructing the synthetic future weather trajectories can include replacing a first portion of each synthetic future weather trajectory with data from a current short-term weather forecast. The first portion can correspond to a near-term period of one to fourteen days from the decision date. In an example, the first fourteen days of each synthetic future weather trajectory can be replaced with data from a current fourteen-day weather forecast, such that near-term weather predictions reflect current forecast information while longer-term weather predictions reflect historical climatological variability.

At operation 1312, predicted soiling losses are generated using the probability and effectiveness of natural cleaning events. The predicted soiling losses can represent temporal degradation of photovoltaic performance due to particulate deposition and restoration of performance due to rainfall-induced cleaning. In an example, predicted soiling losses can be generated by applying a soiling accumulation model that increases soiling loss between cleaning events according to a deposition rate parameter and decreases soiling loss in response to rainfall events exceeding a rain cleaning threshold.

In some implementations, generating the predicted soiling losses can include executing a calibrated soiling model that represents temporal degradation of photovoltaic performance due to particulate deposition. The calibrated soiling model can receive the predicted weather events and generate predicted soiling losses based on when rainfall events occur and whether the rainfall events exceed a rain cleaning threshold sufficient to reduce soiling on photovoltaic modules. In an example, the calibrated soiling model can receive a probabilistic future weather trajectory indicating rainfall events on specific days within an evaluation horizon and generate predicted soiling losses that decrease in response to rainfall events exceeding five millimeters and increase between rainfall events according to a site-specific deposition rate of 0.1% per day.

In some implementations, the calibrated soiling model can be calibrated using historical site data via an optimization algorithm to estimate site-specific parameters including at least one of deposition rates, rain-induced cleaning thresholds, or cleaning efficiency coefficients, among others. The optimization algorithm can minimize a discrepancy between modeled soiling losses and measured soiling losses by iteratively adjusting soiling model parameters. In an example, the calibrated soiling model can be calibrated using five years of historical production data and rainfall measurements via a particle swarm optimization algorithm to estimate a monthly soiling deposition rate for each month of the year, a rain cleaning threshold of five millimeters, and a rain accumulation period of twenty-four hours.

At operation 1313, predicted power output is generated using the predicted weather events and the predicted soiling losses. The predicted power output can represent expected photovoltaic generation over a forward-looking evaluation horizon. In an example, predicted power output can be generated by applying an energy production model to forecast expected photovoltaic generation for a ninety-day evaluation horizon and reducing the expected photovoltaic generation by the predicted soiling losses to compute expected production under soiled conditions.

In some implementations, generating the predicted power output can include applying an energy production model that accounts for seasonal irradiance patterns, sun angle, or temperature effects, among others. The energy production model can forecast expected photovoltaic generation based on variations in solar irradiance, day length, or temperature-dependent performance across different months of the evaluation horizon. In an example, the energy production model can determine that expected production during summer months is higher than expected production during winter months due to increased solar irradiance and longer day length, such that the economic impact of soiling losses is weighted by the expected production level during the evaluation period.

At operation 1314, a predicted energy gain from a candidate manual cleaning event is determined using the predicted power output. The predicted energy gain can represent an incremental energy recovery associated with performing a cleaning event at a decision time relative to continued operation under soiled conditions. In an example, the predicted energy gain can be determined by computing a difference between expected production under clean conditions of 500 megawatt-hours and expected production under soiled conditions of 475 megawatt-hours, resulting in a predicted energy gain of 25 megawatt-hours.

In some implementations, generating each cleaning event scenario can include evaluating two scenarios for each historical year of the long-term historical meteorological data: a first scenario in which the candidate manual cleaning event occurs at a decision time and a second scenario in which no manual cleaning event occurs at the decision time. The first scenario can model soiling loss starting at zero at the decision time and accumulating thereafter according to a deposition rate. The second scenario can model soiling loss continuing to accumulate from a current soiling level without intervention. In an example, for a historical year corresponding to 2015, a first scenario can be evaluated in which a cleaning event resets soiling to zero on March 15 and a second scenario can be evaluated in which soiling continues to accumulate from a current soiling level of 5% on March 15.

At operation 1315, a predicted revenue gain from the candidate manual cleaning event is determined using the predicted energy gain. The predicted revenue gain can represent an incremental revenue recovery associated with performing a cleaning event at a decision time. In an example, the predicted revenue gain can be determined by multiplying the predicted energy gain of 25 megawatt-hours by an energy price of $100 per megawatt-hour, resulting in a predicted revenue gain of $2,500.

In some implementations, determining the predicted revenue gain can include computing a difference between a revenue of the first scenario and a revenue of the second scenario. The revenue of the first scenario can represent expected revenue under clean conditions over the evaluation horizon. The revenue of the second scenario can represent expected revenue under soiled conditions over the evaluation horizon. In an example, the revenue of the first scenario can be $50,000 corresponding to 500 megawatt-hours at $100 per megawatt-hour, and the revenue of the second scenario can be $47,500 corresponding to 475 megawatt-hours at $100 per megawatt-hour, resulting in a predicted revenue gain of $2,500.

At operation 1320, a recommendation for a manual cleaning event is generated based on the predicted revenue gain of the candidate manual cleaning event of each of the plurality of cleaning event scenarios. The recommendation can indicate whether to perform or defer a cleaning event on the photovoltaic array. In an example, the recommendation can indicate that a cleaning event should be performed within a specified timeframe of seven days based on the predicted revenue gains across the plurality of cleaning event scenarios.

In some implementations, generating the recommendation for the manual cleaning event can include computing an expected incremental net benefit based on the predicted revenue gain of the candidate manual cleaning event across the plurality of cleaning event scenarios and comparing the expected incremental net benefit to a configurable threshold. The expected incremental net benefit can be computed as an average of net economic benefit values across the plurality of cleaning event scenarios, where each net economic benefit value represents the predicted revenue gain minus a cleaning cost. In an example, the expected incremental net benefit can be computed as an arithmetic mean of twenty net economic benefit values corresponding to twenty historical years, and the expected incremental net benefit can be compared to a configurable threshold of $1,000 to determine whether to recommend cleaning.

In some implementations, generating the recommendation for the manual cleaning event can include computing a wash viability index defined as a ratio of the expected gross revenue benefit to a cleaning cost. The wash viability index can quantify the economic attractiveness of a cleaning decision relative to the cleaning cost. In an example, the wash viability index can be computed by dividing an expected gross revenue benefit of $3,000 by a cleaning cost of $2,000, resulting in a wash viability index of 1.5 indicating that expected gains exceed the cleaning cost.

In some implementations, generating the recommendation for the manual cleaning event can include computing a probability that the candidate manual cleaning event yields a positive benefit across the plurality of cleaning event scenarios. The probability can be computed by determining a proportion of net economic benefit values that exceed zero. In an example, the probability can be computed by determining that fifteen of twenty net economic benefit values are positive, resulting in a probability of positive benefit of 0.75.

At operation 1330, implementation of the recommendation for the manual cleaning event is caused. The implementation can include generating control signals for a cleaning scheduling system to perform the recommended manual cleaning event on the photovoltaic array. In an example, the implementation can include transmitting a work order to maintenance personnel specifying a cleaning date within a recommended cleaning window of seven days. In an example, the implementation can include activating automated cleaning equipment to initiate cleaning operations on the photovoltaic modules based on the recommendation.

In an example implementation, a photovoltaic wash optimization system operates at a utility-scale solar installation located in a semi-arid climate region. The installation includes 50,000 photovoltaic modules with a total nameplate capacity of 20 megawatts. The system receives real-time production data from supervisory control and data acquisition sensors deployed across the installation, including power output measurements sampled at five-minute intervals, irradiance readings from pyranometers, and module temperature measurements from embedded thermocouples. The system receives historical production data spanning seven years of hourly energy production records, maintenance logs indicating dates of prior manual cleaning events, and rainfall measurements from an on-site meteorological station.

The system calibrates a soiling accumulation model using the seven years of historical production data and rainfall measurements. A particle swarm optimization algorithm executes over 150 iterations to estimate site-specific soiling parameters. The calibration process determines monthly soiling deposition rates ranging from 0.05% per day during winter months to 0.18% per day during summer months when dust activity increases due to dry conditions and agricultural operations in the surrounding area. The calibration process determines a rain cleaning threshold of 4.5 millimeters accumulated within a 24-hour period, below which rainfall events provide insufficient cleaning to reduce soiling on the photovoltaic modules. The calibration process determines a grace period of two days following a cleaning rainfall event during which no soiling accumulation occurs due to residual moisture on module surfaces. The calibrated soiling model achieves an average absolute error of 0.38% between predicted soiling losses and measured soiling losses across the seven-year historical period.

The system constructs synthetic future weather trajectories using 25 years of historical meteorological data from a regional weather station located within 15 kilometers of the installation. For a decision date of April 15, the system extracts daily rainfall amounts, temperature values, and irradiance values from each of the 25 historical years starting from April 15 and extending forward for 90 days through July 14. The system replaces the first 14 days of each synthetic future weather trajectory with data from a current 14-day weather forecast obtained from a numerical weather prediction service. The current weather forecast indicates a 30% probability of rainfall exceeding 5 millimeters within the next seven days and dry conditions expected for days eight through fourteen.

The system generates 25 cleaning event scenarios corresponding to the 25 historical years. For each historical year, the system evaluates two scenarios: a first scenario in which a manual cleaning event occurs on April 15 and a second scenario in which no manual cleaning event occurs. In the first scenario, the soiling model resets soiling loss to zero on April 15 and accumulates soiling thereafter according to the calibrated monthly deposition rates. In the second scenario, the soiling model continues accumulating soiling from a current measured soiling level of 4.2% on April 15.

The system applies an energy production model that accounts for seasonal irradiance patterns at the installation latitude of 35 degrees north. The energy production model determines that expected daily production increases from approximately 85 megawatt-hours per day in mid-April to approximately 110 megawatt-hours per day in late June due to increased solar irradiance and longer day length. The energy production model applies temperature derating coefficients that reduce module efficiency by 0.4% for each degree Celsius above 25 degrees Celsius, accounting for reduced performance during hot summer afternoons.

For a historical year corresponding to 2018, the synthetic weather trajectory indicates no rainfall events exceeding the 4.5 millimeter cleaning threshold during the 90-day evaluation horizon. The soiling model predicts that soiling loss under the second scenario increases from 4.2% on April 15 to 12.8% by July 14, resulting in cumulative energy losses of 680 megawatt-hours over the evaluation horizon. The soiling model predicts that soiling loss under the first scenario increases from 0% on April 15 to 8.6% by July 14, resulting in cumulative energy losses of 410 megawatt-hours over the evaluation horizon. The predicted energy gain from cleaning for the 2018 scenario is 270 megawatt-hours.

For a historical year corresponding to 2021, the synthetic weather trajectory indicates a rainfall event of 18 millimeters occurring on May 3, which exceeds the 4.5 millimeter cleaning threshold and resets soiling to zero. The soiling model predicts that soiling loss under the second scenario increases from 4.2% on April 15 to 2.1% on May 3 due to the rainfall cleaning event, then increases to 9.4% by July 14, resulting in cumulative energy losses of 390 megawatt-hours over the evaluation horizon. The soiling model predicts that soiling loss under the first scenario increases from 0% on April 15 to 0% on May 3 due to the rainfall cleaning event, then increases to 7.3% by July 14, resulting in cumulative energy losses of 280 megawatt-hours over the evaluation horizon. The predicted energy gain from cleaning for the 2021 scenario is 110 megawatt-hours.

The system applies energy prices from a power purchase agreement specifying a fixed rate of $45 per megawatt-hour for all energy delivered to the grid. The system computes predicted gross revenue gains for each of the 25 cleaning event scenarios by multiplying the predicted energy gains by the energy price. The predicted revenue gains range from $2,250 for scenarios with early rainfall cleaning events to $12,150 for scenarios with prolonged dry periods during the high-production summer months.

The system receives a cleaning cost of $8,500 for a full-site manual cleaning event, which includes labor costs for a crew of six workers over two days, water costs of 50,000 gallons, and equipment rental costs for pressure washing systems.

The system computes an expected gross revenue benefit of $9,000 as an arithmetic mean of the 25 predicted revenue gains (i.e., gross revenue gain). The system computes a wash viability index of 1.06 by dividing the expected gross revenue gain of $9,000 by the cleaning cost of $8,500.

The system compares the wash viability index of 1.06 to an upper threshold of 1.2 and a lower threshold of 0.8. The wash viability index falls between the upper threshold and the lower threshold, indicating marginal economic benefit from cleaning on April 15. The system generates a re-evaluate recommendation indicating that the cleaning decision should be reassessed for an alternative timeframe.

The system evaluates additional cleaning event scenarios for a decision date of April 22, one week after the original decision date. The updated 14-day weather forecast indicates dry conditions expected for the full 14-day period with less than 10% probability of rainfall exceeding 5 millimeters. The system generates 25 cleaning event scenarios for the April 22 decision date and computes an expected gross revenue gain of $10,500, a wash viability index of 1.24, and a probability of positive benefit of 0.72.

The system compares the wash viability index of 1.24 to the upper threshold of 1.2. The wash viability index exceeds the upper threshold, indicating that expected economic benefit from cleaning on April 22 substantially exceeds the cleaning cost. The system generates a clean recommendation indicating that a manual cleaning event should be performed within a recommended cleaning window of April 22 through April 29. The recommendation includes a confidence summary indicating a 72% probability of positive benefit and the expected gross revenue gain of $10,500.

The system transmits the clean recommendation to a cleaning scheduling system. The cleaning scheduling system generates a work order specifying a cleaning date of April 24, allocates a crew of six workers, schedules water delivery of 50,000 gallons, and reserves pressure washing equipment for the cleaning event. The cleaning scheduling system transmits task assignments to maintenance personnel and confirmation requests to the photovoltaic wash optimization system.

The technical advantages of the implementation include accurate prediction of soiling accumulation behavior through site-specific calibration of the soiling model using seven years of historical data, which reduces prediction error compared to generic soiling models that do not account for local climate conditions and dust sources. The implementation provides probabilistic quantification of cleaning decision outcomes by evaluating 25 distinct weather scenarios derived from 25 years of historical meteorological data, which captures the range of possible future weather outcomes and associated economic impacts. The implementation accounts for seasonal energy production by weighting the economic impact of soiling losses according to expected production levels during the evaluation horizon, such that cleaning actions performed prior to high-production summer months receive appropriate economic valuation. The implementation integrates short-term weather forecast information with long-term climatological variability by replacing the first 14 days of each synthetic weather trajectory with current forecast data, which provides improved near-term accuracy while preserving the probabilistic representation of longer-term weather uncertainty. The implementation provides explicit economic and risk-based decision metrics including the wash viability index and probability of positive benefit, which enable operators to make informed cleaning decisions that balance expected economic gains against cleaning costs and weather-related uncertainty.

The foregoing detailed description includes illustrative examples of various aspects and implementations and provides an overview or framework for understanding the nature and character of the claimed aspects and implementations. The drawings provide illustration and a further understanding of the various aspects and implementations and are incorporated in and constitute a part of this specification.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices). The operations described in this specification can be implemented as operations performed by a data processing apparatus on data stored on one or more computer-readable storage devices or received from other sources.

The terms “computing device” or “component” encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a model stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating an output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks. The processor and the memory can be supplemented by, or incorporated in, special purpose logic circuitry.

While operations are depicted in the drawings in a particular order, such operations are not required to be performed in the particular order shown or in sequential order, and all illustrated operations are not required to be performed. Actions described herein can be performed in a different order. The separation of various system components does not require separation in all implementations, and the described program components can be included in a single hardware or software product.

The phraseology and terminology used herein is for the purpose of description and should not be regarded as limiting. Any references to implementations or elements or acts of the systems and methods herein referred to in the singular may also embrace implementations including a plurality of these elements, and any references in plural to any implementation or element or act herein may also embrace implementations including only a single element. Any implementation disclosed herein may be combined with any other implementation or embodiment.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

What is claimed is:

1. A method, comprising:
generating a plurality of cleaning event scenarios for a photovoltaic array by:
generating predicted weather events by combining long-term historical meteorological data with short-term weather forecasts to estimate a probability and effectiveness of natural cleaning events;
generating predicted soiling losses using the probability and effectiveness of natural cleaning events;
generating predicted power output using the predicted weather events and the predicted soiling losses;
determining a predicted energy gain from a candidate manual cleaning event using the predicted power output; and
determining a predicted revenue gain from the candidate manual cleaning event using the predicted energy gain;
generating a recommendation for a manual cleaning event based on the predicted revenue gain of the candidate manual cleaning event of each of the plurality of cleaning event scenarios; and
causing implementation of the recommendation for the manual cleaning event.

2. The method of claim 1, wherein generating the predicted weather events comprises constructing synthetic future weather trajectories using actual historical weather data from a decision date forward.

3. The method of claim 2, wherein constructing the synthetic future weather trajectories comprises replacing a first portion of each synthetic future weather trajectory with data from a current short-term weather forecast.

4. The method of claim 1, wherein generating the predicted soiling losses comprises executing a calibrated soiling model that represents temporal degradation of photovoltaic performance due to particulate deposition, wherein the calibrated soiling model is calibrated using historical site data via an optimization algorithm to estimate site-specific parameters including at least one of deposition rates, rain-induced cleaning thresholds, and cleaning efficiency coefficients.

5. The method of claim 1, wherein generating the predicted weather events comprises processing ensemble weather forecasts that provide multiple possible weather trajectories with associated probabilities, wherein the ensemble weather forecasts are distinct from deterministic weather forecasts that provide a single predicted weather trajectory.

6. The method of claim 1, wherein generating the predicted power output comprises applying an energy production model that accounts for seasonal irradiance patterns, sun angle, and temperature effects.

7. The method of claim 1, wherein generating the recommendation for the manual cleaning event comprises:
computing a wash viability index based on the predicted revenue gain of the candidate manual cleaning event across the plurality of cleaning event scenarios and a cleaning cost; and
comparing the wash viability index to a configurable threshold.

8. The method of claim 7, wherein generating the recommendation for the manual cleaning event includes prioritizing cleaning across multiple photovoltaic sites based on a ranking of the wash viability index computed for each of the multiple photovoltaic sites.

9. The method of claim 1, wherein generating the recommendation for the manual cleaning event comprises computing a probability that the candidate manual cleaning event yields a positive benefit across the plurality of cleaning event scenarios.

10. The method of claim 1, wherein generating each cleaning event scenario comprises evaluating two scenarios for each historical year of the long-term historical meteorological data:
a first scenario in which the candidate manual cleaning event occurs at a decision time, and
a second scenario in which no manual cleaning event occurs at the decision time, wherein determining the predicted revenue gain comprises computing a difference between a revenue of the first scenario and a revenue of the second scenario.

11. A system, comprising:
one or more processors; and
a non-transitory computer-readable medium storing instructions that, when executed by the one or more processors, cause the one or more processors to:
generate a plurality of cleaning event scenarios for a photovoltaic array by:
generating predicted weather events by combining long-term historical meteorological data with short-term weather forecasts to estimate a probability and effectiveness of natural cleaning events;
generating predicted soiling losses using the probability and effectiveness of natural cleaning events;
generating predicted power output using the predicted weather events and the predicted soiling losses;
determining a predicted energy gain from a candidate manual cleaning event using the predicted power output; and
determining a predicted revenue gain from the candidate manual cleaning event using the predicted energy gain;
generate a recommendation for a manual cleaning event based on the predicted revenue gain of the candidate manual cleaning event of each of the plurality of cleaning event scenarios; and
cause implementation of the recommendation for the manual cleaning event.

12. The system of claim 11, wherein generating the predicted weather events comprises constructing synthetic future weather trajectories using actual historical weather data from a decision date forward.

13. The system of claim 12, wherein constructing the synthetic future weather trajectories comprises replacing a first portion of each synthetic future weather trajectory with data from a current short-term weather forecast.

14. The system of claim 11, wherein generating the predicted soiling losses comprises executing a calibrated soiling model that represents temporal degradation of photovoltaic performance due to particulate deposition, wherein the calibrated soiling model is calibrated using historical site data via an optimization algorithm to estimate site-specific parameters including at least one of deposition rates, rain-induced cleaning thresholds, and cleaning efficiency coefficients.

15. The system of claim 11, wherein generating the predicted weather events comprises processing ensemble weather forecasts that provide multiple possible weather trajectories with associated probabilities, wherein the ensemble weather forecasts are distinct from deterministic weather forecasts that provide a single predicted weather trajectory.

16. The system of claim 11, wherein generating the predicted power output comprises applying an energy production model that accounts for seasonal irradiance patterns, sun angle, and temperature effects.

17. The system of claim 11, wherein generating the recommendation for the manual cleaning event comprises:
computing a wash viability index based on the predicted revenue gain of the candidate manual cleaning event across the plurality of cleaning event scenarios and a cleaning cost; and
comparing the wash viability index to a configurable threshold.

18. The system of claim 17, wherein generating the recommendation for the manual cleaning event includes prioritizing cleaning across multiple photovoltaic sites based on a ranking of the wash viability index computed for each of the multiple photovoltaic sites.

19. The system of claim 11, wherein generating the recommendation for the manual cleaning event comprises computing a probability that the candidate manual cleaning event yields a positive benefit across the plurality of cleaning event scenarios.

20. The system of claim 11, wherein generating each cleaning event scenario comprises evaluating two scenarios for each historical year of the long-term historical meteorological data:
a first scenario in which the candidate manual cleaning event occurs at a decision time, and
a second scenario in which no manual cleaning event occurs at the decision time, wherein determining the predicted revenue gain comprises computing a difference between a revenue of the first scenario and a revenue of the second scenario.
